(19) United States
(12) Patent Application Publication
(10) Pub. No.: US 2024/0339395 A1
(43) Pub. Date: Oct. 10, 2024

(54) SEMICONDUCTOR DEVICE

(71) Applicant: Samsung Electronics Co., Ltd., Suwon-si (KR)

(72) Inventors: Byungchul KANG, Suwon-si (KR); Rakhwan KIM, Suwon-si (KR); Jeongik KIM, Suwon-si (KR); Chunghwan SHIN, Suwon-si (KR); Daeun KIM, Suwon-si (KR); Seongdong LIM, Suwon-si (KR)

(73) Assignee: Samsung Electronics Co., Ltd., Suwon-si (KR)

(21) Appl. No.: 18/494,183

(22) Filed: Oct. 25, 2023

(30) Foreign Application Priority Data
Apr. 7, 2023 (KR) 10-2023-0045853

(51) Int. Cl. H01L 23/522; H01L 21/768; H01L 21/8238; H01L 23/532; H01L 27/092

(52) U.S. Cl. CPC H01L 23/5226; H01L 21/76846; H01L 21/76876; H01L 21/823814; H01L 21/823871; H01L 23/53223; H01L 23/53238; H01L 23/53266; H01L 27/092

(57) ABSTRACT

A semiconductor device may include a substrate including an active pattern, a channel pattern on the active pattern and including semiconductor patterns that are vertically stacked and spaced apart from each other, a source/drain pattern connected to the semiconductor patterns, a gate electrode on the semiconductor patterns and including inner electrodes between neighboring semiconductor patterns and an outer electrode on an uppermost semiconductor pattern, and a gate contact structure electrically connected to the outer electrode. The gate contact structure may include a lower gate contact on a top surface of the outer electrode and an upper gate contact on the lower gate contact. The lower gate contact may include a first liner pattern, a first filling pattern on the first liner pattern, and a nucleation pattern between the first liner pattern and the first filling pattern. The upper gate contact may not include the nucleation pattern.

### CROSS-REFERENCE TO RELATED APPLICATION

This U.S. nonprovisional application claims priority under 35 U.S.C § 119 to Korean Patent Application No. 10-2023-0045853 filed on Apr. 7, 2023 in the Korean Intellectual Property Office, the disclosure of which is hereby incorporated by reference in its entirety.

### BACKGROUND

Inventive concepts relate to a semiconductor device, and more particularly, to a semiconductor device including a field effect transistor.

A semiconductor device may have an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

Some embodiments of inventive concepts provide a semiconductor device with increased reliability.

Some embodiments of inventive concepts provide a semiconductor device with improved electrical properties.

According to an embodiment of inventive concepts, a semiconductor device may include a substrate including an active pattern; a channel pattern on the active pattern, the channel pattern including a plurality of semiconductor patterns that are vertically stacked and spaced apart from each other; a source/drain pattern connected to the plurality of semiconductor patterns; a gate electrode on the plurality of semiconductor patterns, the gate electrode including a plurality of inner electrodes between neighboring semiconductor patterns of the plurality of semiconductor patterns and an outer electrode on an uppermost semiconductor pattern of the plurality of semiconductor patterns; and a gate contact structure electrically connected to the outer electrode. The gate contact structure may include a lower gate contact on a top surface of the outer electrode and an upper gate contact on the lower gate contact. The lower gate contact may include a first liner pattern, a first filling pattern on the first liner pattern, and a nucleation pattern between the first liner pattern and the first filling pattern.

According to an embodiment of inventive concepts, a semiconductor device may include a substrate including an active pattern; a channel pattern on the active pattern, the channel pattern including a plurality of semiconductor patterns that are vertically stacked and spaced apart from each other; a source/drain pattern connected to the plurality of semiconductor patterns; a gate electrode on the plurality of semiconductor patterns; and a gate contact structure electrically connected to the gate electrode. The gate contact structure may include a lower gate contact on the gate electrode and an upper gate contact on the lower gate contact. The lower gate contact may include a first liner pattern, a first filling pattern on the first liner pattern, and a nucleation pattern between the first liner pattern and the first filling pattern. The nucleation pattern may include metal and boron. The nucleation pattern may have a first boron concentration. The first liner pattern and the first filling pattern each may have a second boron concentration. The first boron concentration may be greater than the second boron concentration.

According to an embodiment of inventive concepts, a semiconductor device may include a substrate including an active pattern; a device isolation layer on the substrate and defining the active pattern; a channel pattern on the active pattern, the channel pattern including a plurality of semiconductor patterns that are vertically stacked and spaced apart from each other; a source/drain pattern connected to the plurality of semiconductor patterns; a gate electrode on the plurality of semiconductor patterns; a gate dielectric layer between the gate electrode and neighboring semiconductor patterns among the plurality of semiconductor patterns; a gate spacer on a sidewall of the gate electrode; a gate contact structure electrically connected to the gate electrode, the gate contact structure including a lower gate contact in direct contact with the gate electrode and an upper gate contact on the lower gate contact; an active contact structure electrically connected to the source/drain pattern, the active contact structure including a lower active contact adjacent to the source/drain pattern and an upper active contact on the lower active contact; a metal-semiconductor compound layer between the active contact structure and the source/drain pattern; a first metal layer on the gate contact structure, the first metal layer including a power line and a first wiring line electrically connected to the active contact structure; and a second metal layer on the first metal layer, the second metal layer including a second wiring line electrically connected to first metal layer. A top surface of the upper gate contact and a top surface of the upper active contact may be coplanar with each other. A level of a bottom surface of the upper gate contact may be higher than a level of a bottom surface of the upper active contact.

### BRIEF DESCRIPTION OF DRAWINGS

FIGS. 1 to 3 illustrate conceptual views showing logic cells of a semiconductor device according to some embodiments of inventive concepts.

FIG. 4 illustrates a plan view showing a semiconductor device according to some embodiments of inventive concepts.

FIGS. 5A, 5B, 5C, and 5D illustrate cross-sectional views respectively taken along lines A-A′, B-B′, C-C′, and D-D′ of FIG. 4.

FIG. 6 illustrates an enlarged view showing section B of FIG. 5.

FIGS. 7A to 17D illustrate cross-sectional views showing a method of fabricating a semiconductor device according to some embodiments of inventive concepts.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

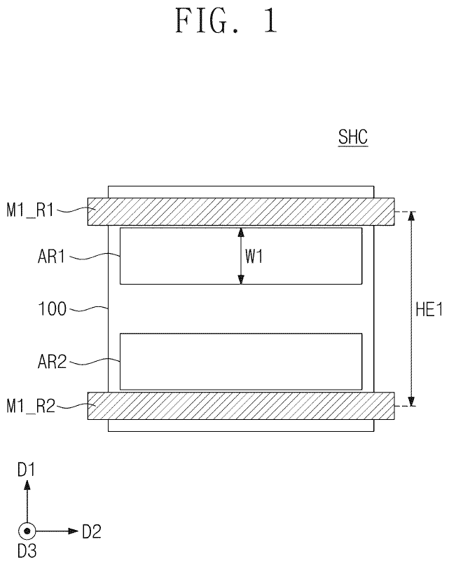

FIGS. 1 to 3 illustrate conceptual views showing logic cells of a semiconductor device according to some embodiments of inventive concepts.

Referring to FIG. 1, a single height cell SHC may be provided. For example, a substrate 100 may be provided thereon with a first power line M1_R1 and a second power line M1_R2. The first power line M1_R1 may be a path for providing a source voltage VSS, for example, a ground voltage. The second power line M1_R2 may be a path for providing a drain voltage VDD, for example, a power voltage.

The single height cell SHC may be defined between the first power line M1_R1 and the second power line M1_R2. The single height cell SHC may include one first active region AR1 and one second active region AR2. One of the first and second active regions AR1 and AR2 may be a PMOSFET region, and the other of the first and second active regions AR1 and AR2 may be an NMOSFET region. For example, the single height cell SHC may have a complementary metal oxide semiconductor (CMOS) structure provided between the first power line M1_R1 and the second power line M1_R2.

Each of the first and second active regions AR1 and AR2 may have a width W1 in a first direction D1. A vertical height HE1 may be defined as a length in the first direction D1 of the single height cell SHC. The vertical height HE1 may be substantially the same as a distance (e.g., a pitch) between the first power line M1_R1 and the second power line M1_R2.

The single height cell SHC may constitute one logic cell. In this description, the logic cell may mean a logic device, such as AND, OR, XOR, XNOR, and inverter, that performs a specific function. For example, the logic cell may include transistors for constituting a logic device, and may also include wiring lines that connect the transistors to each other.

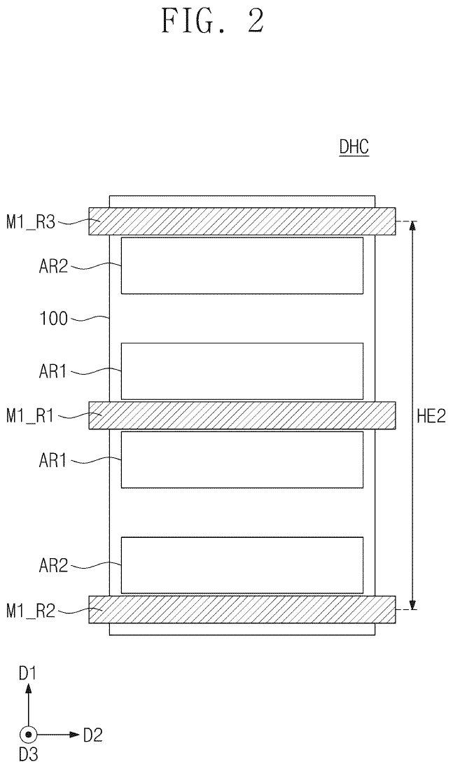

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a source voltage VSS.

The double height cell DHC may be defined between the second power line M1_R2 and the third power line M1_R3. The double height cell DHC may include two first active regions AR1 and two second active regions AR2.

One of the two second active regions AR2 may be adjacent to the second power line M1_R2. The other of the two second active regions AR2 may be adjacent to the third power line M1_R3. The two first active regions AR1 may be adjacent to the first power line M1_R1. When viewed in plan, the first power line M1_R1 may be disposed between the two first active regions AR1.

A second vertical height HE2 may be defined to indicate a length in the first direction D1 of the double height cell DHC. The second vertical height HE2 may be about twice the vertical height HE1 of FIG. 1. The two first active regions AR1 of the double height cell DHC may be collectively connected together to act as one active region.

In inventive concepts, the double height cell DHC shown in FIG. 2 may be defined as a multi-height cell. Although not shown, the multi-height cell may include a triple height cell whose cell height is about three times that of the single height cell SHC.

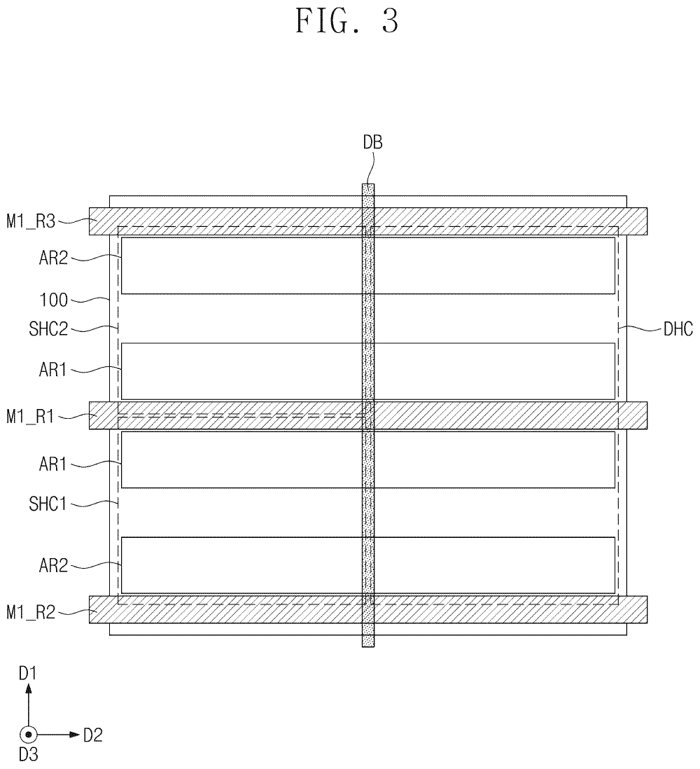

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first and second single height cells SHC1 and SHC2.

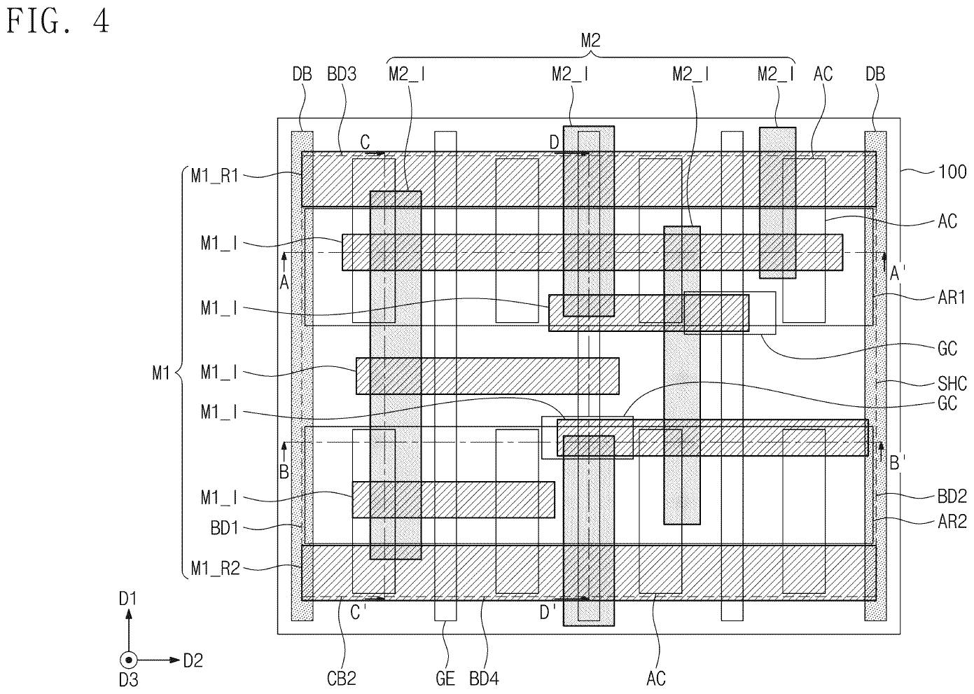

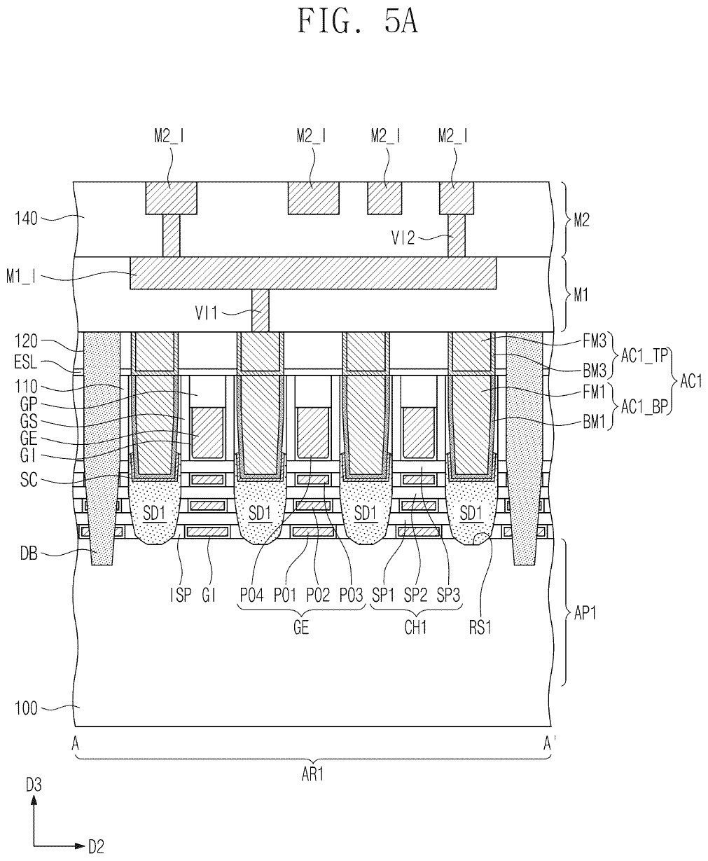

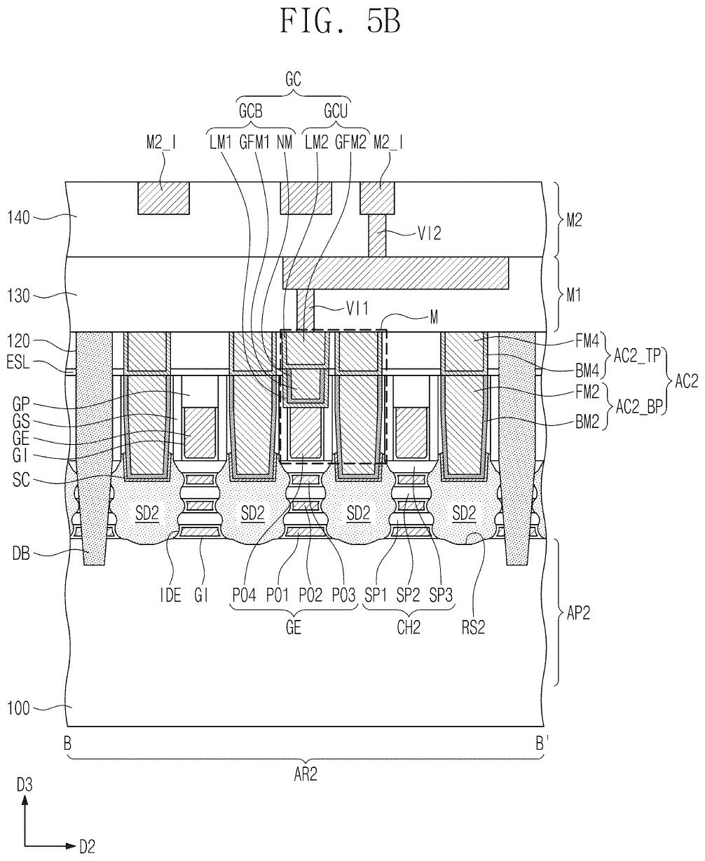

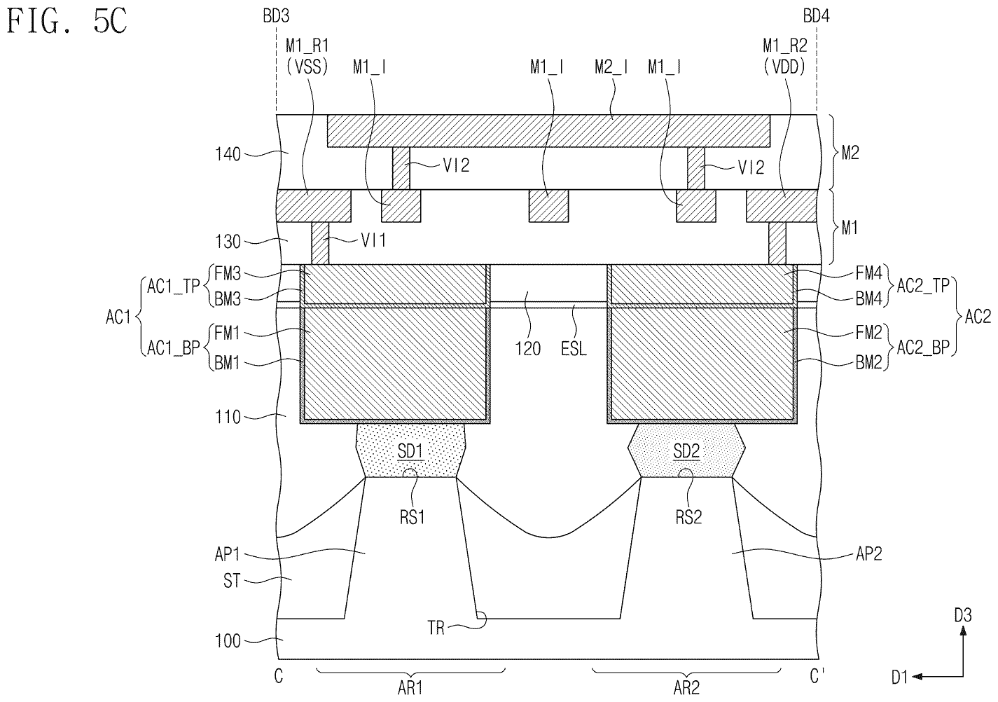

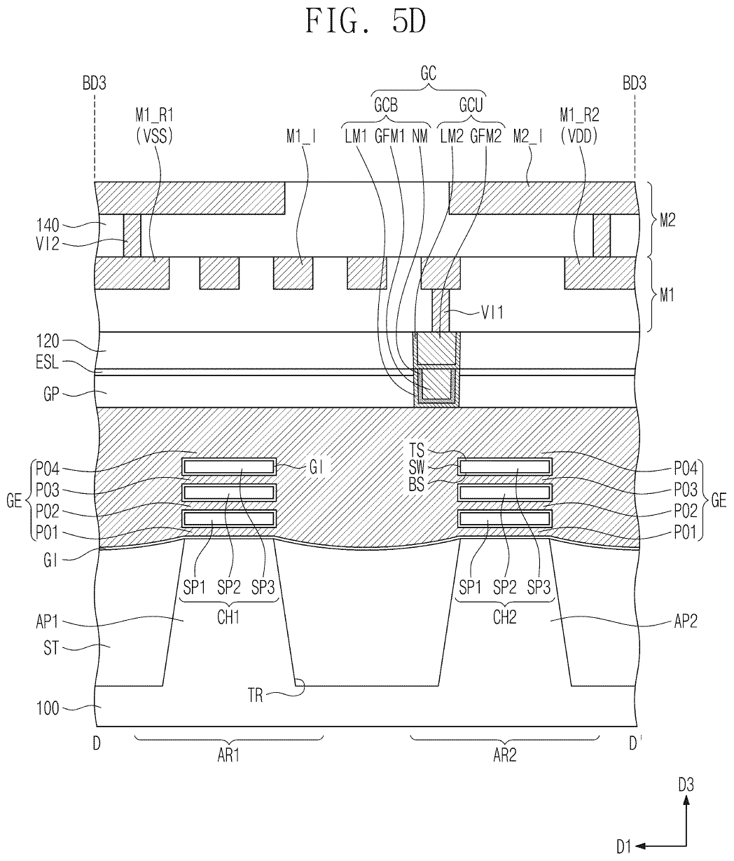

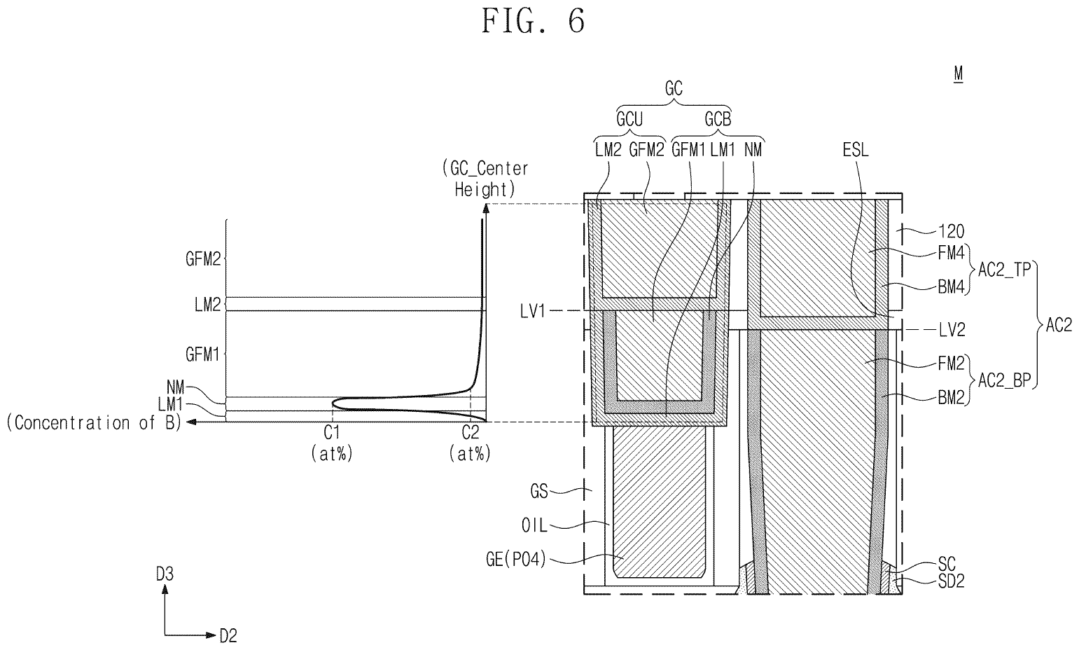

FIG. 4 illustrates a plan view showing a semiconductor device according to some embodiments of inventive concepts. FIGS. 5A, 5B, 5C, and 5D illustrate cross-sectional views respectively taken along lines A-A′, B-B′, C-C′, and D-D′ of FIG. 4. FIG. 6 illustrates an enlarged view showing section B of FIG. 5. A semiconductor device depicted in FIGS. 4 and 5A to 5D may be a detailed example of the single height cell SHC shown in FIG. 1.

Referring to FIGS. 4 and 5A to 5D, a single height cell SHC may be provided on a substrate 100. The single height cell SHC may be provided thereon with logic transistors included in a logic circuit. The substrate 100 may be a compound semiconductor substrate or a semiconductor substrate including silicon, germanium, or silicon-germanium. For example, the substrate 100 may be a silicon substrate.

The substrate 100 may include a first active region AR1 and a second active region AR2. Each of the first and second active regions AR1 and AR2 may extend in a second direction D2. In an embodiment, the first active region AR1 may be an NMOSFET region, and the second active region AR2 may be a PMOSFET region.

A first active pattern AP1 and a second active pattern AP2 may be defined by a trench TR formed on an upper portion of the substrate 100. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be vertically protruding portions of the substrate 100.

A device isolation layer ST may be provided on the substrate 100. The device isolation layer ST may fill the trench TR. The device isolation layer ST may include a silicon oxide layer. The device isolation layer ST may not cover any of first and second channel patterns CH1 and CH2 which will be discussed below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3).

Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon, for example, monocrystalline silicon. In an embodiment of inventive concepts, the first, second, and third semiconductor patterns SP1, SP2, and SP3 may be stacked nano-sheets.

A plurality of first source/drain patterns SD1 may be provided on the first active pattern AP1. A plurality of first recesses RS1 may be formed on an upper portion of the first active pattern AP1. The first source/drain patterns SD1 may be correspondingly provided in the first recesses RS1. The first source/drain patterns SD1 may be impurity regions of a first conductivity type (e.g., n-type). The first channel pattern CH1 may be interposed between a pair of first source/drain patterns SD1. For example, the pair of first source/drain patterns SD1 may be connected to each other through the stacked first, second, and third semiconductor patterns SP1, SP2, and SP3.

A plurality of second source/drain patterns SD2 may be provided on the second active pattern AP2. A plurality of second recesses RS2 may be formed on an upper portion of the second active pattern AP2. The second source/drain patterns SD2 may be correspondingly provided in the second recesses RS2. The second source/drain patterns SD2 may be impurity regions of a second conductivity type (e.g., p-type). The second channel pattern CH2 may be interposed between a pair of second source/drain patterns SD2. For example, the pair of second source/drain patterns SD2 may be connected to each other through the stacked first, second, and third semiconductor patterns SP1, SP2, and SP3.

The first and second source/drain patterns SD1 and SD2 may be epitaxial patterns formed by a selective epitaxial growth (SEG) process. For example, each of the first and second source/drain patterns SD1 and SD2 may have a top surface higher than that of the third semiconductor pattern SP3. For another example, at least one of the first and second source/drain patterns SD1 and SD2 may have a top surface at substantially the same level as that of a top surface of the third semiconductor pattern SP3.

In an embodiment of inventive concepts, the first source/drain patterns SD1 may include the same semiconductor element (e.g., Si) as that of the substrate 100. The second source/drain patterns SD2 may include a semiconductor element (e.g., SiGe) whose lattice constant is greater than that of a semiconductor element of the substrate 100. Therefore, a pair of second source/drain patterns SD2 may provide the second channel pattern CH2 with compressive stress.

In an embodiment of inventive concepts, the second source/drain pattern SD2 may have an uneven embossing shape on a sidewall thereof. For example, the sidewall of the second source/drain pattern SD2 may have a wavy profile. The sidewall of the second source/drain pattern SD2 may protrude toward first, second, and third inner electrodes PO1, PO2, and PO3 of a gate electrode GE which will be discussed below.

Gate electrodes GE may be provided on the first and second channel patterns CH1 and CH2. Etch of the gate electrodes GE may extend in a first direction D1, while running across the first and second channel patterns CH1 and CH2. Each of the gate electrodes GE may vertically overlap the first and second channel patterns CH1 and CH2. The gate electrodes GE may be arranged at a first pitch in the second direction D2.

The gate electrode GE may include a first inner electrode PO1 interposed between the first semiconductor pattern SP1 and the active pattern AP1 or AP2, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 5D, the gate electrode GE may be provided on a top surface TS, a bottom surface BS, and opposite sidewalls SW of each of the first, second, and third semiconductor patterns SP1, SP2, and SP3. For example, a transistor according to the present embodiment may be a three-dimensional field effect transistor (e.g., MBCFET or GAAFET) in which the gate electrode GE three-dimensionally surrounds the first and second channel patterns CH1 and CH2.

On the first active region AR1, inner spacers ISP may be correspondingly interposed between the first source/drain pattern SD1 and the first, second, and third inner electrodes PO1, PO2, and PO3 of the gate electrode GE. Each of the first, second, and third inner electrodes PO1, PO2, and PO3 of the gate electrode GE may be spaced apart from the first source/drain pattern SD1 across the inner spacer ISP. The inner spacer ISP may limit and/or prevent a leakage current from the gate electrode GE.

Referring back to FIGS. 4 and 5A to 5D, a pair of gate spacers GS may be disposed on opposite sidewalls of the outer electrode PO4 of the gate electrode GE. The gate spacers GS may extend in the first direction D1 along the gate electrode GE. In an embodiment, the gate spacers GS may include at least one selected from SiCN, SiCON, and SiN. In another embodiment, the gate spacers GS may include a multiple layer formed of at least two selected from SiCN, SiCON, and SiN. In an embodiment of inventive concepts, the gate spacer GS may include a silicon-containing dielectric material. The gate spacer GS may serve as an etch stop layer when active contact structures (see AC of FIG. 4) are formed as discussed below. The gate spacer GS may be caused to form the active contact structures AC in a self-alignment manner.

A gate capping pattern GP may be provided on the gate electrode GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include at least one selected from SiON, SiCN, SiCON, and SiN.

A gate dielectric layer GI may be interposed between the gate electrode GE and the first channel pattern CH1 and between the gate electrode GE and the second channel pattern CH2. The gate dielectric layer GI may cover the top surface TS, the bottom surface BS, and the opposite sidewalls SW of each of the first, second, and third semiconductor patterns SP1, SP2, and SP3. The gate dielectric layer GI may cover a top surface of the device isolation layer ST below the gate electrode GE.

In an embodiment of inventive concepts, the gate dielectric layer GI may include one or more of a silicon oxide layer, a silicon oxynitride layer, and a high-k dielectric layer. For example, the gate dielectric layer GI may have a structure in which a silicon oxide layer and a high-k dielectric layer are stacked. The high-k dielectric layer may include a high-k dielectric material whose dielectric constant is greater than that of a silicon oxide layer. For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Alternatively, a semiconductor device according to inventive concepts may include a negative capacitance field effect transistor that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing of less than about 60 mV/decade at room temperature.

The ferroelectric material layer may have ferroelectric properties. The ferroelectric material layer may include, for example, one or more of hafnium oxide, hafnium zirconium oxide, barium strontium titanium oxide, and lead zirconium titanium oxide. For example, the hafnium zirconium oxide may be a material in which hafnium oxide is doped with zirconium (Zr). For another example, the hafnium zirconium oxide may be a compound of hafnium (Hf), zirconium (Zr), and oxygen (O).

The ferroelectric material layer may further include impurities doped therein. For example, the impurities may include at least one selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of impurities included in the ferroelectric material layer may be changed depending on what ferroelectric material is included in the ferroelectric material layer.

When the ferroelectric material layer includes hafnium oxide, the ferroelectric material layer may include at least one of impurities such as gadolinium (Gd), silicon (Si), zirconium (Zr), aluminum (Al), and yttrium (Y).

When the impurities are aluminum (Al), the ferroelectric material layer may include about 3 to 8 atomic percent aluminum. In this description, the ratio of impurities may be a ratio of aluminum to the sum of hafnium and aluminum.

When the impurities are silicon (Si), the ferroelectric material layer may include about 2 to about 10 atomic percent silicon. When the impurities are yttrium (Y), the ferroelectric material layer may include about 2 to about 10 atomic percent yttrium. When the impurities are gadolinium (Gd), the ferroelectric material layer may include about 1 to about 7 atomic percent gadolinium. When the impurities are zirconium (Zr), the ferroelectric material layer may include about 50 to about 80 atomic percent zirconium.

The paraelectric material layer may have paraelectric properties. The paraelectric material layer may include, for example, at least one selected from silicon oxide and high-k metal oxide. The metal oxide included in the paraelectric material layer may include, for example, one or more of hafnium oxide, zirconium oxide, and aluminum oxide, but inventive concepts are not limited thereto.

The ferroelectric and paraelectric material layers may include the same material. The ferroelectric material layer may have ferroelectric properties, but the paraelectric material layer may not have ferroelectric properties. For example, when the ferroelectric material layer and the paraelectric material layer include hafnium oxide, the hafnium oxide included in the ferroelectric material layer may have a crystal structure different from that of the hafnium oxide included in the paraelectric material layer.

The ferroelectric material layer may have a thickness having ferroelectric properties. The thickness of the ferroelectric material layer may range, for example, from about 0.5 nm to about 10 nm, but inventive concepts are not limited thereto. Because ferroelectric materials have their own critical thickness that exhibits ferroelectric properties, the thickness of the ferroelectric material layer may depend on ferroelectric material.

For example, the gate dielectric layer GI may include a single ferroelectric material layer. For another example, the gate dielectric layer GI may include a plurality of ferroelectric material layers that are spaced apart from each other. The gate dielectric layer GI may have a stack structure in which a plurality of ferroelectric material layers are alternately stacked with a plurality of paraelectric material layers.

Referring back to FIGS. 4 and 5A to 5D, the gate electrode GE may include a first metal pattern and a second metal pattern on the first metal pattern. The first metal pattern may be provided on the gate dielectric layer GI and may be adjacent to the first, second, and third semiconductor patterns SP1, SP2, and SP3. The first metal pattern may include a work-function metal that controls a threshold voltage of a transistor. A thickness and composition of the first metal pattern may be adjusted to achieve a desired threshold voltage of a transistor. For example, the first, second, and third inner electrodes PO1, PO2, and PO3 of the gate electrode GE may be formed of the first metal pattern or the work-function metal.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). The first metal pattern may include a plurality of stacked work-function metal layers.

The second metal pattern may include metal whose resistance is less than that of the first metal pattern. For example, the second metal pattern may include at least one metal selected from tungsten (W), aluminum (Al), titanium (Ti), and tantalum (Ta). For example, the outer electrode PO4 of the gate electrode GE may include a first metal pattern and a second metal pattern on the first metal pattern.

A first interlayer dielectric layer 110 may be provided on the substrate 100. The first interlayer dielectric layer 110 may cover the gate spacers GS and the first and second source/drain patterns SD1 and SD2. The first interlayer dielectric layer 110 may have a top surface substantially coplanar with that of the gate capping pattern GP and that of the gate spacer GS.

The first interlayer dielectric layer 110 may be provided thereon with an etch stop layer ESL that covers the gate capping pattern GP. For example, the etch stop layer ESL may include a silicon nitride layer. A second interlayer dielectric layer 120 may be disposed on the etch stop layer ESL. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include a silicon oxide layer.

The single height cell SHC may have a first boundary BD1 and a second boundary BD2 that are opposite to each other in the second direction D2. The first and second boundaries BD1 and BD2 may extend in the first direction D1. The single height cell SHC may have a third boundary BD3 and a fourth boundary BD4 that are opposite to each other in the first direction D1. The third and fourth boundaries BD3 and BD4 may extend in the second direction D2.

The single height cell SHC may be provided on its opposite sides with a pair of separation structures DB that are opposite to each other in the second direction D2. For example, the pair of separation structures DB may be correspondingly provided on first and second boundaries BD1 and BD2 of the single height cell SHC. The separation structure DB may extend in the first direction D1 parallel to the gate electrodes GE. A pitch between the separation structure DB and its adjacent gate electrode GE may be the same as the first pitch.

The separation structure DB may penetrate the first interlayer dielectric layer 110, the etch stop layer ESL, and the second interlayer dielectric layer 120 to extend into the first and second active patterns AP1 and AP2. The separation structure DB may penetrate an upper portion of each of the first and second active patterns AP1 and AP2. The separation structure DB may electrically separate an active region of the single height cell SHC from an active region of an adjacent another cell.

First and second active contact structures AC1 and AC2 may be provided to penetrate the first interlayer dielectric layer 110, the etch stop layer ESL, and the second interlayer dielectric layer 120 to come into electrical connection with the first and second source/drain patterns SD1 and SD2, respectively. A pair of second active contact structures AC2 may be correspondingly provided on opposite sides of the gate electrode GE. When viewed in plan, the first and second active contact structures AC1 and AC2 may each have a bar shape that extends in the first direction D1.

The first and second active contact structures AC1 and AC2 may be a self-aligned contact. For example, the gate capping pattern GP and the gate spacer GS may be used to form the first and second active contact structures AC1 and AC2 in a self-alignment manner. For example, the first and second active contact structures AC1 and AC2 may be disposed adjacent to a sidewall of the gate spacer GS. Although not shown, the first and second active contact structures AC1 and AC2 may cover a portion of the top surface of the gate capping pattern GP.

A metal-semiconductor compound layer SC, such as a silicide layer, may be interposed between the first active contact structure AC1 and the first source/drain pattern SD1 and between the second active contact structure AC2 and the second source/drain pattern SD2. The first and second active contact structures AC1 and AC2 may be electrically connected through the metal-semiconductor compound layers SC to the first and second source/drain patterns SD1 and SD2, respectively. For example, the metal-semiconductor compound layer SC may include at least one selected from titanium silicide, tantalum silicide, tungsten silicide, nickel silicide, and cobalt silicide.

A contact structure GC may be provided to penetrate the second interlayer dielectric layer 120 and the gate capping pattern GP to come into electrical connection with a corresponding one of the gate electrodes GE. When viewed in plan, the gate contact structure GC may be disposed to overlap a corresponding one of the first active region AR1 and the second active region AR2. For example, the gate contact structure GC may be provided on the second active pattern AP2. With reference to FIGS. 5A, 5B, and 6, the following will describe in detail the gate contact structure GC, the first active contact structure AC1, and the second active contact structure AC2 according to an embodiment of inventive concepts.

Although not shown, in another embodiment of inventive concepts, an upper dielectric pattern may fill an upper portion of the second active contact structure AC2 adjacent to the gate contact structure GC. The upper dielectric pattern may have a bottom surface lower than that of the gate contact structure GC. For example, the upper dielectric pattern may cause the second active contact structure AC2 adjacent to the gate contact structure GC to have a top surface lower than the bottom surface of the gate contact structure GC. It may thus be possible to limit and/or prevent a short-circuit occurring due to contact between the gate contact structure GC and its adjacent second active contact structure AC2.

A first metal layer M1 may be provided in the third interlayer dielectric layer 130. For example, the first metal layer M1 may include a first power line M1_R1, a second power line M1_R2, and first wiring lines M1_I. The lines M1_R1, M1_R2, and M1_I of the first metal layer M1 may parallel extend in the second direction D2.

For example, the first and second power lines M1_R1 and M1_R2 may be respectively provided on the third and fourth boundaries BD3 and BD4 of the single height cell SHC. The first power line M1_R1 may extend in the second direction D2 along the third boundary BD3. The second power line M1_R2 may extend in the second direction D2 along the fourth boundary BD4.

The first wiring lines M1_I of the first metal layer M1 may be disposed between the first and second power lines M1_R1 and M1_R2. The first wiring lines M1_I of the first metal layer M1 may be arranged at a second pitch along the first direction D1. The second pitch may be less than the first pitch. Each of the first wiring lines M1_I may have a line-width less than that of each of the first and second power lines M1_R1 and M1_R2.

The first metal layer M1 may further include first vias VI1. The first vias VI1 may be correspondingly provided below the lines M1_R1, M1_R2, and M1_I of the first metal layer M1. The first via VI1 may electrically connect the active contact structure AC1 or AC2 to one of the lines M1_R1, M1_R2, M1_R3, and M1_I of the first metal layer M1. The first via VI1 may electrically connect the gate contact structure GC to one of the lines M1_R1, M1_R2, and M1_I of the first metal layer M1.

A certain line and its underlying first via VI1 of the first metal layer M1 may be formed by individual processes. For example, the certain line and its underlying first via VI1 of the first metal layer M1 may be formed by a single damascene process. A sub-20 nm process may be employed to fabricate a semiconductor device according to the present embodiment.

A second metal layer M2 may be provided in the fourth interlayer dielectric layer 140. The second metal layer M2 may include a plurality of second wiring lines M2_I. The second wiring lines M2_I of the second metal layer M2 may each have a linear or bar shape that extends in the first direction D1. For example, the second wiring lines M2_I may parallel extend in the first direction D1.

The second metal layer M2 may further include second vias VI2 that are correspondingly provided below the second wiring lines M2_I. A certain line of the first metal layer M1 may be electrically through the second via VI2 to a corresponding line of the second metal layer M2. For example, a wiring line and its underlying second via VI2 of the second metal layer M2 may be simultaneously formed in a dual damascene process.

The first and second metal layers M1 and M2 may have their wiring lines that include the same or different conductive materials. For example, the wiring lines of the first and second metal layers M1 and M2 may include at least one metallic material selected from aluminum, copper, tungsten, molybdenum, ruthenium, and cobalt. Although not shown, other metal layers (e.g., M3, M4, M5, etc.) may be additionally stacked on the fourth interlayer dielectric layer 140. Each of the stacked metal layers may include wiring lines for routing between cells.

The gate contact structure GC and the first and second active contact structures AC1 and AC2 will be further discussed in detail below with reference to FIGS. 5A, 5B, and 6. The gate contact structure GC may vertically overlap the gate electrode GE. The gate contact structure GC may be electrically connected to the outer electrode PO4 of the gate electrode GE. A width in the second direction D2 of the gate contact structure GC may be greater than a width in the second direction D2 of the outer electrode PO4.

The gate contact structure GC may include a lower gate contact GCB on the outer electrode PO4 and an upper gate contact GCU on the lower gate contact GCB. For example, the gate contact structure GC may have a double stacked structure that includes the lower gate contact GCB and the upper gate contact GCU.

The lower gate contact GCB may include a first liner pattern LM1, a first filling pattern GFM1, and a nucleation pattern NM. The first liner pattern LM1 may be provided on bottom and lateral surfaces of a first gate contact recess (see GC_RS1 of FIG. 14B) which will be discussed below. The first liner pattern LM1 may include at least one metal selected from aluminum, copper, tungsten, molybdenum, and cobalt.

The first filling pattern GFM1 may be provided on the first liner pattern LM1. The first filling pattern GFM1 may fill a first gate contact recess (see GC_RS1 of FIG. 14B) which will be discussed below. For example, the first filling pattern GFM1 may be provided to fill an empty space on the first liner pattern LM1. The first filling pattern GFM1 may include at least one metal selected from aluminum, copper, tungsten, molybdenum, and cobalt.

The nucleation pattern NM may be interposed between the first liner pattern LM1 and the first filling pattern GFM1. For example, the nucleation pattern NM may extend from bottom to lateral surfaces of the first filling pattern GFM1. The nucleation pattern NM may extend to a bottom surface of the upper gate contact GCU. The nucleation pattern NM may include boron (B) and at least one metal selected from aluminum, copper, tungsten, molybdenum, and cobalt.

The upper gate contact GCU may include a second liner pattern LM2 and a second filling pattern GFM2. The upper gate contact GCU may not include the nucleation pattern NM. For example, the nucleation pattern NM may be omitted without being interposed between the second liner pattern LM2 and the second filling pattern GFM2. The bottom surface of the upper gate contact GCU may be in direct contact with a top surface of the first liner pattern LM1, a top surface of the first filling pattern GFM1, and a top surface of the nucleation pattern NM. For example, a bottom surface of the second liner pattern LM2 may be in direct contact with the top surface of the first liner pattern LM1, the top surface of the first filling pattern GFM1, and the top surface of the nucleation pattern NM.

As the nucleation pattern NM is included only in the lower gate contact GCB of the gate contact structure GC, it may be possible to limit and/or prevent the occurrence of void in the gate contact structure GC. In addition, no seam or slit may be created in the gate contact structure GC, and thus it may be possible to improve profile failure of the gate contact structure GC.

According to an embodiment of inventive concepts, the gate contact structure GC may have a double stacked structure, and the upper gate contact GCU may not include the nucleation pattern NM, with the result that the gate contact structure GC may decrease in overall resistance. Only the lower gate contact GCB may include the nucleation pattern NM whose resistance is greater than that of the first liner pattern LM1 and that of the first filling pattern GFM1, and it may thus be possible to reduce an average resistance of the gate contact structure GC. A semiconductor device according to inventive concepts may consequently increase in electrical properties.

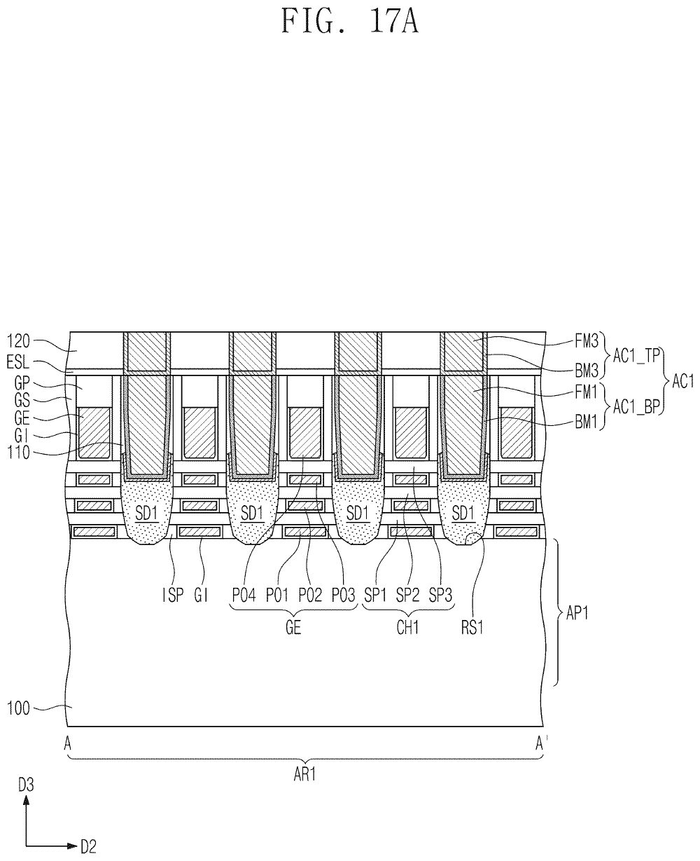

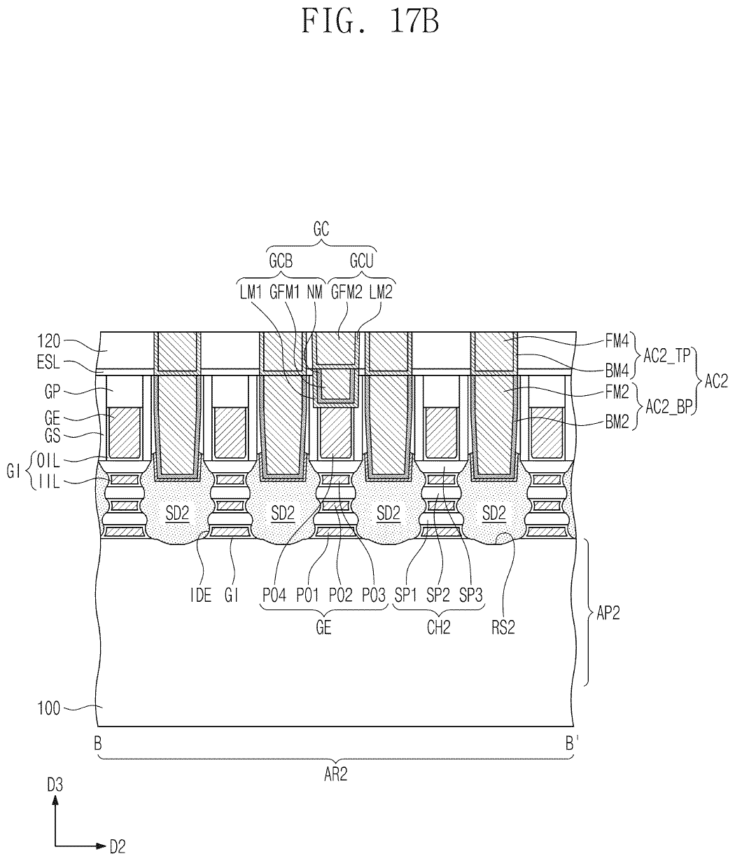

The second liner pattern LM2 may be provided on bottom and lateral surfaces of a second gate contact recess (see GC_RS2 of FIG. 16B) which will be discussed below. The second liner pattern LM2 may include at least one metal selected from aluminum, copper, tungsten, molybdenum, and cobalt.

The second filling pattern GFM2 may be provided on the second liner pattern LM2. The second filling pattern GFM2 may fill a second gate contact recess (see GC_RS2 of FIG. 14B) which will be discussed below. For example, the second filling pattern GFM2 may be provided to fill an empty space on the second liner pattern LM2. The second filling pattern GFM2 may include at least one metal selected from aluminum, copper, tungsten, molybdenum, and cobalt.

Referring back to FIG. 6, the nucleation pattern NM may have a first boron concentration C1, and each of the first and second liner patterns LM1 and LM2 may have a second boron concentration C2. The first boron concentration C1 may be defined to refer to a concentration of boron (B) contained in the nucleation pattern NM. The second boron concentration C2 may be defined to refer to a concentration of boron (B) contained in each of the first and second liner patterns LM1 and LM2. The first boron concentration C1 may be greater than the second boron concentration C2. For example, the first boron concentration C1 may range from about 0.1 at % to about 15 at %. The second boron concentration C2 may converge to zero.

The nucleation pattern NM may be a tungsten layer containing boron (B). The nucleation pattern NM may serve as an incubation layer for uniformly depositing a tungsten layer. For example, as a B₂H₆ gas is used to form a seed layer for uniformly depositing a tungsten layer, the nucleation pattern NM may contain boron as an impurity.

Each of the second liner pattern LM2 and the second filling pattern GFM2 may have a third boron concentration. The third boron concentration may be defined to refer to a concentration of boron (B) contained in each of the second liner pattern LM2 and the second filling pattern GFM2. The first boron concentration C1 may be greater than the third boron concentration. The third boron concentration may be the same as or less than the second boron concentration C2. The third boron concentration may converge to zero.

Referring to the graph of FIG. 6, it may be possible to ascertain a boron concentration according to a height of the gate contact structure GC. An increase in height of the gate contact structure GC may induce an exponential increase and decrease in boron concentration. A period in which a slope of a concentration profile is abruptly changed may be a period in which the nucleation pattern NM is provided in the gate contact structure GC. For example, in the period in which the nucleation pattern NM is provided, the boron concentration may increase from the second boron concentration C2 to the first boron concentration C1, and then decrease back to the second boron concentration C2 from the first boron concentration C1.

The nucleation pattern NM may include boron (B) and at least one metal selected from aluminum, copper, tungsten, molybdenum, and cobalt, for example, may include boron and tungsten. The nucleation pattern NM may be a tungsten single layer deposited by performing a pulsed nucleation layer (PNL) process. Since the nucleation pattern NM is deposited by the PNL process, the nucleation pattern NM may be non-crystalline or amorphous. The PNL process may be performed with a similar mechanism to that of an atomic layer deposition (ALD) process.

Each of the first and second liner patterns LM1 and LM2 may include at least one metal selected from aluminum, copper, tungsten, molybdenum, and cobalt, for example, may include tungsten. The first and second liner patterns LM1 and LM2 may be a tungsten layer deposited by performing a physical vapor deposition (PVD) process. The first and second liner patterns LM1 and LM2 may be crystalline.

Each of the first and second filling patterns GFM1 and GFM2 may include at least one metal selected from aluminum, copper, tungsten, molybdenum, and cobalt, for example, may include tungsten. The first and second filling patterns GFM1 and GFM2 may be a tungsten layer deposited by performing a chemical vapor deposition (CVD) process. The first and second filling patterns GFM1 and GFM2 may be crystalline.

The first active contact structure AC1 and the second active contact structure AC2 may vertically overlap the first source/drain pattern SD1 and the second source/drain pattern SD2, respectively. The first active contact structure AC1 and the second active contact structure AC2 may be electrically connected to the first source/drain pattern SD1 and the second source/drain pattern SD2, respectively.

The first active contact structure AC1 may include a first lower active contact AC1_BP on the first source/drain pattern SD1 and a first upper active contact AC1_TP on the first lower active contact AC1_BP. The second active contact structure AC2 may include a second lower active contact AC2_BP on the second source/drain pattern SD2 and a second upper active contact AC2_TP on the second lower active contact AC2_BP. For example, each of the first and second active contact structures AC1 and AC2 may have a double stacked structure.

The first lower active contact AC1_BP may include a first barrier pattern BM1 and a first conductive pattern FM1. The first barrier pattern BM1 may be provided on bottom and lateral surfaces of the first conductive pattern FM1. For example, the first barrier pattern BM1 may extend from the bottom to lateral surfaces of the first conductive pattern FM1. The metal-semiconductor compound layer SC may be interposed between the first source/drain pattern SD1 and the bottom surface of the first barrier pattern BM1 and between the first source/drain pattern SD1 and a portion of the lateral surface of the first barrier pattern BM1.

The second lower active contact AC2_BP may include a second barrier pattern BM2 and a second conductive pattern FM2. The second barrier pattern BM2 may be provided on bottom and lateral surfaces of the second conductive pattern FM2. For example, the second barrier pattern BM2 may extend from the bottom to lateral surfaces of the second conductive pattern FM2. The metal-semiconductor compound layer SC may be interposed between the second source/drain pattern SD2 and the bottom surface of the second barrier pattern BM2 and between the second source/drain pattern SD2 and a portion of the lateral surface of the second barrier pattern BM2.

The first and second barrier patterns BM1 and BM2 may include a metal layer or a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer. The first and second conductive patterns FM1 and FM2 may include at least one metal selected from aluminum, copper, tungsten, molybdenum, and cobalt.

The first upper active contact AC1_TP may include a third barrier pattern BM3 and a third conductive pattern FM3. The third barrier pattern BM3 may be provided on bottom and lateral surfaces of the third conductive pattern FM3. For example, the third barrier pattern BM3 may extend from the bottom to lateral surfaces of the third conductive pattern FM3.

The second upper active contact AC2_TP may include a fourth barrier pattern BM4 and a fourth conductive pattern FM4. The fourth barrier pattern BM4 may be provided on bottom and lateral surfaces of the fourth conductive pattern FM4. For example, the fourth barrier pattern BM4 may extend from the bottom to lateral surfaces of the fourth conductive pattern FM4.

The third and fourth barrier pattern BM3 and BM4 may include at least one metal selected from aluminum, copper, tungsten, molybdenum, and cobalt, for example, may include tungsten. The third and fourth barrier patterns BM3 and BM4 may be a tungsten layer deposited by performing a physical vapor deposition (PVD) process. The third and fourth barrier patterns BM3 and BM4 may be crystalline. The third and fourth metal patterns FM3 and FM4 may include at least one metal selected from aluminum, copper, tungsten, molybdenum, and cobalt.

Referring back to FIG. 6, a top surface of the upper gate contact GCU may be substantially coplanar with that of the second upper active contact AC2_TP. The bottom surface of the upper gate contacts GCU may be higher than that of the second upper active contact AC2_TP. For example, the bottom surface of the upper gate contact GCU may be located at a level LV1 higher than a level LV2 of the bottom surface of the second upper active contact AC2_TP. The level LV1 of the bottom surface of the upper gate contact GCU may be the same as a level of a top surface of the etch stop layer ESL. The level LV2 of the bottom surface of the second upper active contact AC2_TP may be the same as a level of a bottom surface of the etch stop layer ESL. This may be caused by the fact that the gate contact structure GC and the second active contact structure AC2 are formed by performing independent fabrication processes without being formed at the same time.

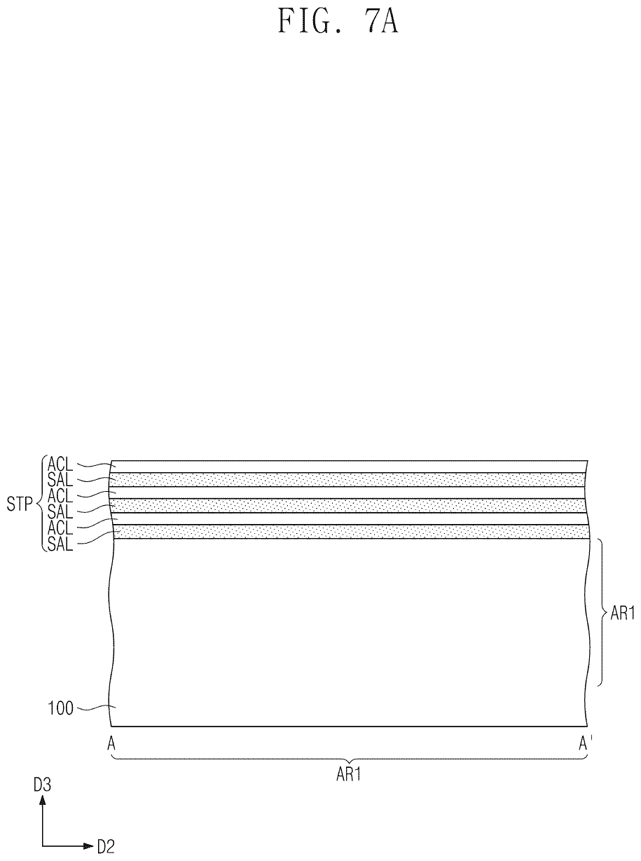

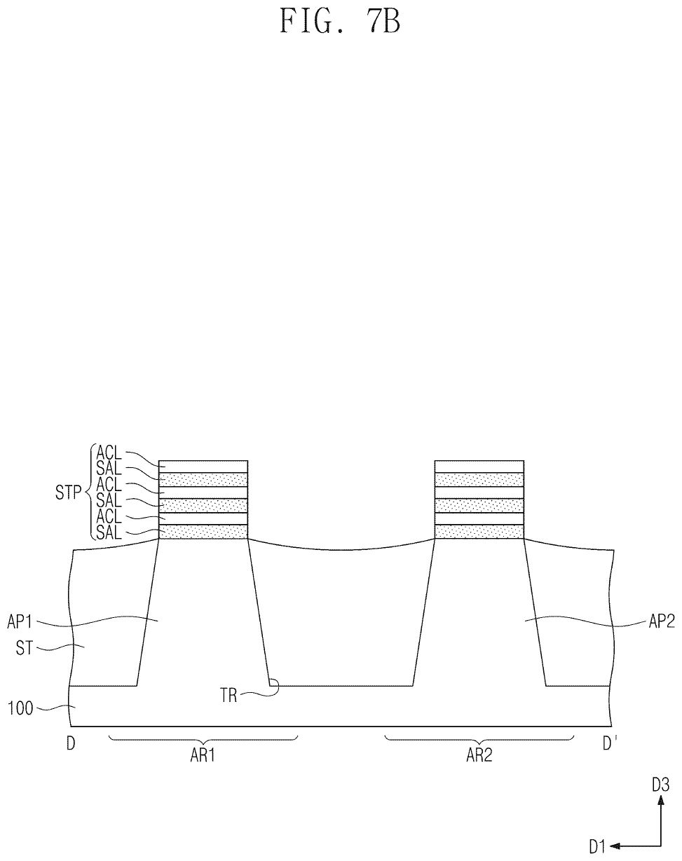

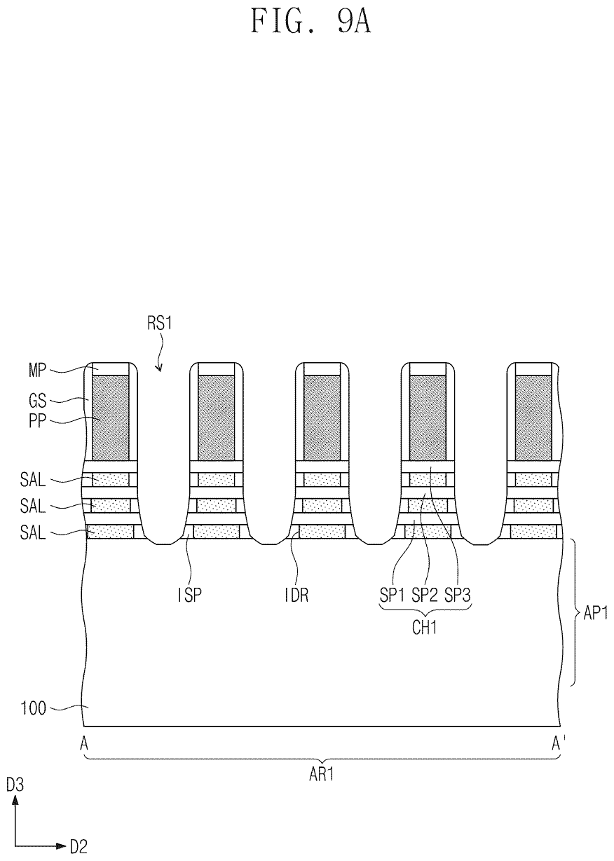

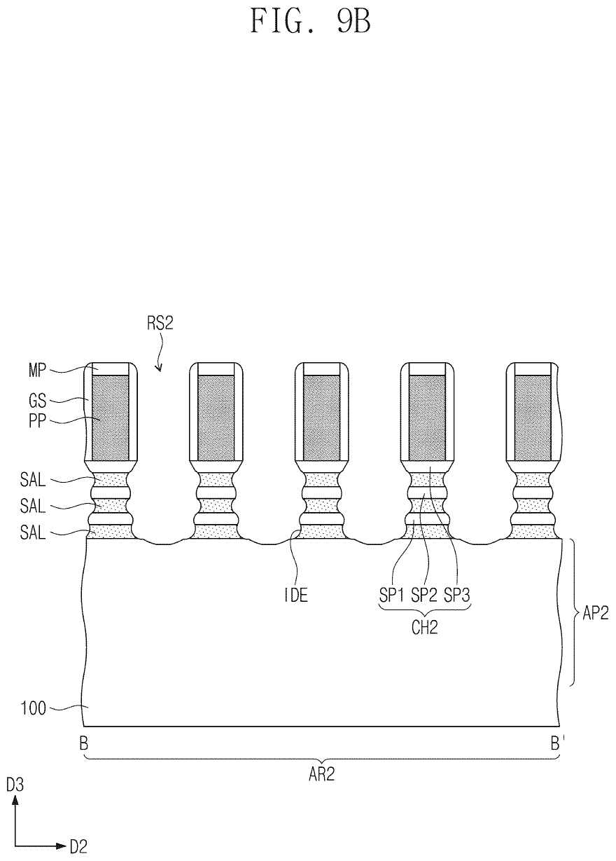

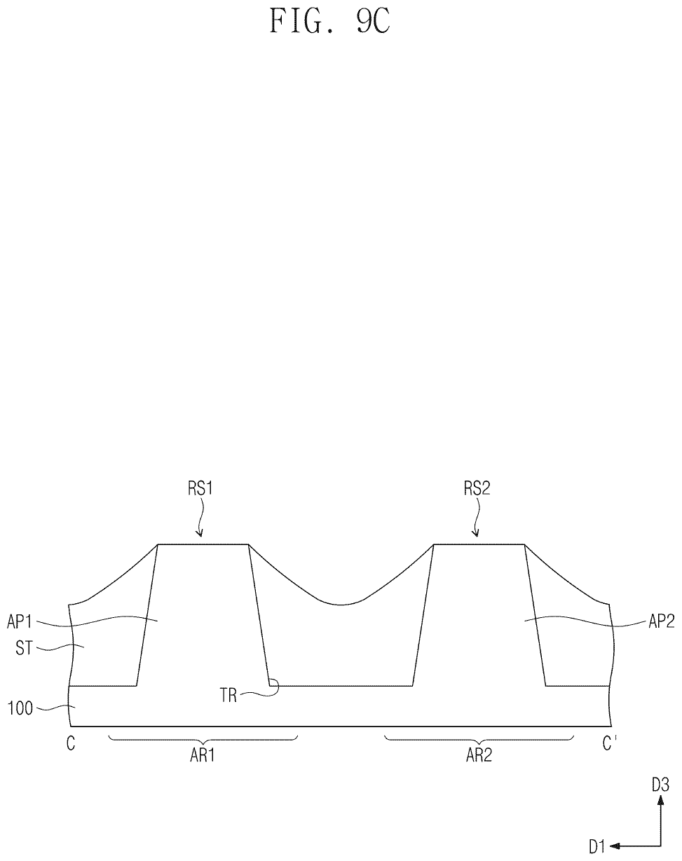

FIGS. 7A to 17D illustrate cross-sectional views showing a method of fabricating a semiconductor device according to some embodiments of inventive concepts. In detail, FIGS. 7A, 8A, 9A, 10A, 11a, 12A, 13A, 14A, 15A, 16A, and 17A illustrate cross-sectional views taken along line A-A′ of FIG. 4. FIGS. 9B, 10B, 11B, 12B, 13b, 14B, 15B, 16B, and 17B illustrate cross-sectional views taken along line B-B′ of FIG. 4. FIGS. 9C, 10C, 11C, 12C, 13C, 14C, 15C, 16C, and 17C illustrate cross-sectional views taken along line C-C′ of FIG. 4. FIGS. 7B, 8B, 11D, 12D, 13D, 14D, 15D, 16D, and 17D illustrate cross-sectional views taken along line D-D′ of FIG. 4.

Referring to FIGS. 7A and 7B, a substrate 100 may be provided which includes a first active region AR1 and a second active region AR2. Active layers ACL and sacrificial layers SAL may be alternately formed on the substrate 100. The active layers ACL may include one of silicon (Si), germanium (Ge), and silicon-germanium (SiGe), and the sacrificial layers SAL may include another of silicon (Si), germanium (Ge), and silicon-germanium (SiGe).

The sacrificial layer SAL may include a material having an etch selectivity with respect to the active layer ACL. For example, the active layers ACL may include silicon (Si), and the sacrificial layers SAL may include silicon-germanium (SiGe). Each of the sacrificial layers SAL may have a germanium concentration of about 10 at % to about 30 at %.

Mask patterns may be formed on each of the first and second active regions AR1 and AR2 of the substrate 100. The mask pattern may have a linear or bar shape that extends in a second direction D2.

A patterning process may be performed in which the mask patterns are used as an etching mask to form a trench TR that defines a first active pattern AP1 and a second active pattern AP2. The first active pattern AP1 may be formed on the first active region AR1. The second active pattern AP2 may be formed on the second active region AR2.

A stack pattern STP may be formed on each of the first and second active patterns AP1 and AP2. The stack pattern STP may include the active layers ACL and the sacrificial layers SAL that are alternately stacked. During the patterning process, the stack pattern STP may be formed together with the first and second active patterns AP1 and AP2.

A device isolation layer ST may be formed to fill the trench TR. For example, a dielectric layer may be formed on an entire surface of the substrate 100 to cover the stack patterns STP and the first and second active patterns AP1 and AP2. The dielectric layer may be recessed until the stack patterns STP are exposed, and thus the device isolation layer ST may be formed.

The device isolation layer ST may include a dielectric material, such as a silicon oxide layer. The stack patterns STP may be exposed upwardly from the device isolation layer ST. For example, the stack patterns STP may vertically protrude upwards from the device isolation layer ST.

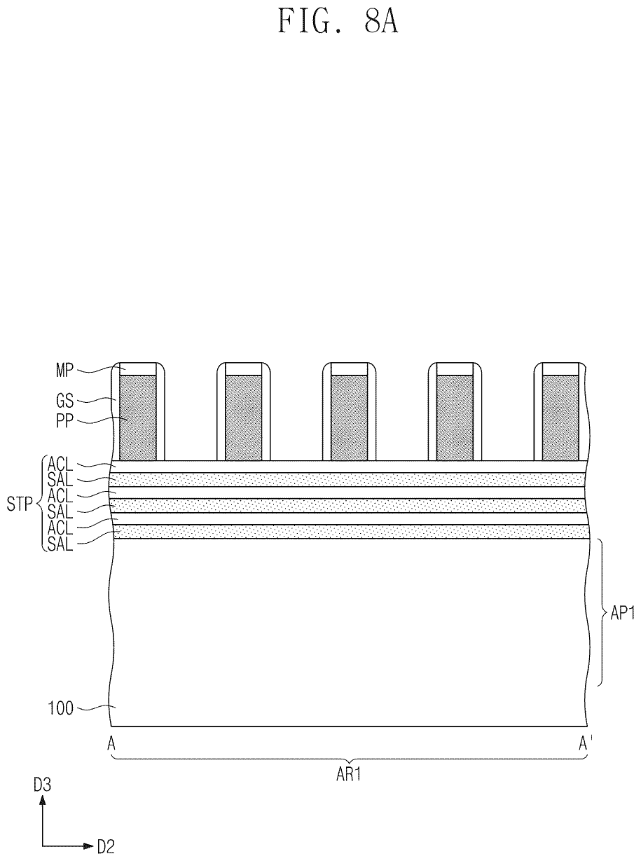

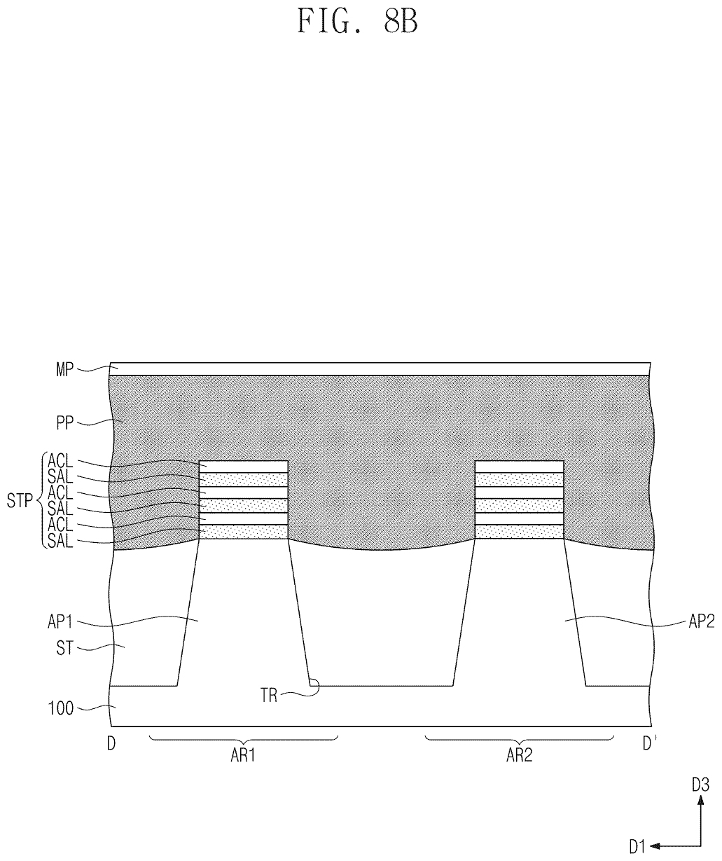

Referring to FIGS. 8A and 8B, sacrificial patterns PP may be formed on the substrate 100, running across the stack patterns STP. Each of the sacrificial patterns PP may be formed to have a linear or bar shape that extends in a first direction D1. The sacrificial patterns PP may be arranged at a first pitch along the second direction D2.

For example, the formation of the sacrificial patterns PP may include forming a sacrificial layer on the entire surface of the substrate 100, forming hardmask patterns MP on the sacrificial layer, and using the hardmask patterns MP as an etching mask to pattern the sacrificial layer. The sacrificial layer may include polysilicon.

A pair of gate spacers GS may be formed on opposite sidewalls of each of the sacrificial patterns PP. The formation of the gate spacers GS may include conformally forming a gate spacer layer on the entire surface of the substrate 100 and anisotropically etching the gate spacer layer. In an embodiment of inventive concepts, the gate spacer GS may be a multiple layer including at least two layers.

Referring to FIGS. 9A to 9C, first recesses RS1 may be formed in the stack pattern STP on the first active pattern AP1. Second recesses RS2 may be formed in the stack pattern STP on the second active pattern AP2. During the formation of the first and second recesses RS1 and RS2, the device isolation layer ST may further be recessed on opposite sides of each of the first and second active patterns AP1 and AP2 (see FIG. 9C).

For example, the hardmask patterns MP and the gate spacers GS may be used as an etching mask such that the stack pattern STP on the first active pattern AP1 may be etched to form the first recesses RS1. The first recess RS1 may be formed between a pair of sacrificial patterns PP.

The active layers ACL may be formed into first, second, and third semiconductor patterns SP1, SP2, and SP3 that are sequentially stacked between neighboring first recesses RS1. A first channel pattern CH1 may be constituted by the first, second, and third semiconductor patterns SP1, SP2, and SP3 between neighboring first recesses RS1.

The first recess RS1 may be formed between neighboring sacrificial patterns PP. A width in the second direction D2 of the first recess RS1 may decrease with decreasing distance from the substrate 100.

The first recess RS1 may expose the sacrificial layers SAL. A selective etching process may be performed on the exposed sacrificial layers SAL. The etching process may include a wet etching process that selectively etches only silicon-germanium. In the etching process, each of the sacrificial layers SAL may be indented to form an indent region IDR. The indent region IDR may allow the sacrificial layer SAL to have a concave sidewall. A dielectric layer may be formed in the first recess RS1, filling the indent regions IDR. The sacrificial layers SAL and the first, second, and third semiconductor patterns SP1, SP2, and SP3 exposed by the first recess RS1 may become a seed layer for the dielectric layer. The dielectric layer may be a crystalline dielectric layer grown on a crystalline semiconductor included in the sacrificial layers SAL and the first, second, and third semiconductor patterns SP1, SP2, and SP3.

An inner spacer ISP may be formed to fill the indent region IDR. For example, the formation of the inner spacer ISP may include wet-etching an epitaxial dielectric layer until sidewalls of the first, second, and third semiconductor patterns SP1, SP2, and SP3 are exposed. Therefore, the epitaxial dielectric layer may remain only in the indent region IDR, thereby constituting the inner spacer ISP.

Referring back to FIGS. 9A to 9C, the second recesses RS2 in the stack pattern STP on the second active pattern AP2 may be formed by a method similar to that used for forming the first recesses RS1. The sacrificial layers SAL exposed by the second recess RS2 may undergo a selective etching process to form indent regions IDE on the second active pattern AP2. The indent regions IDE may cause the second recess RS2 to have a wavy inner sidewall. The inner spacers ISP may not be formed in the indent regions IDE on the second active pattern AP2. A second channel pattern CH2 may be constituted by the first, second, and third semiconductor patterns SP1, SP2, and SP3 between neighboring second recesses RS2.

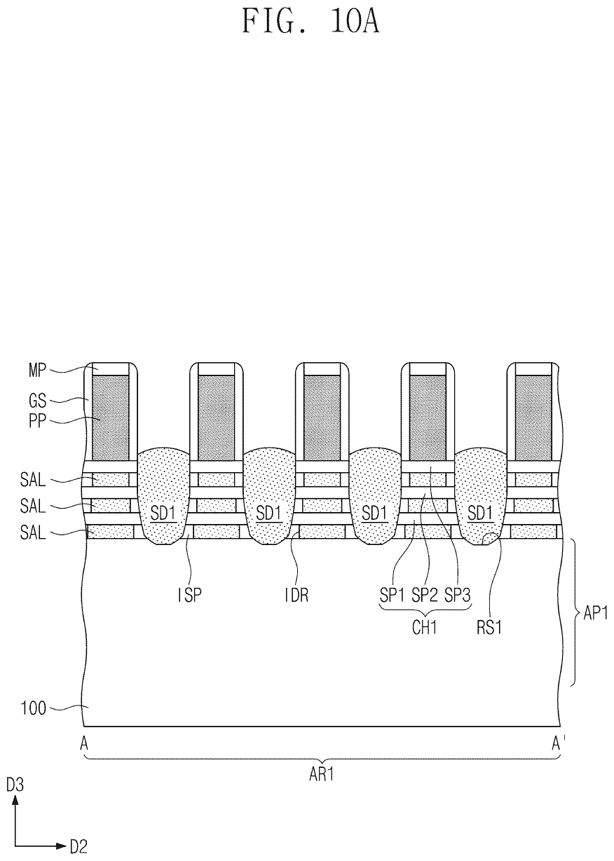

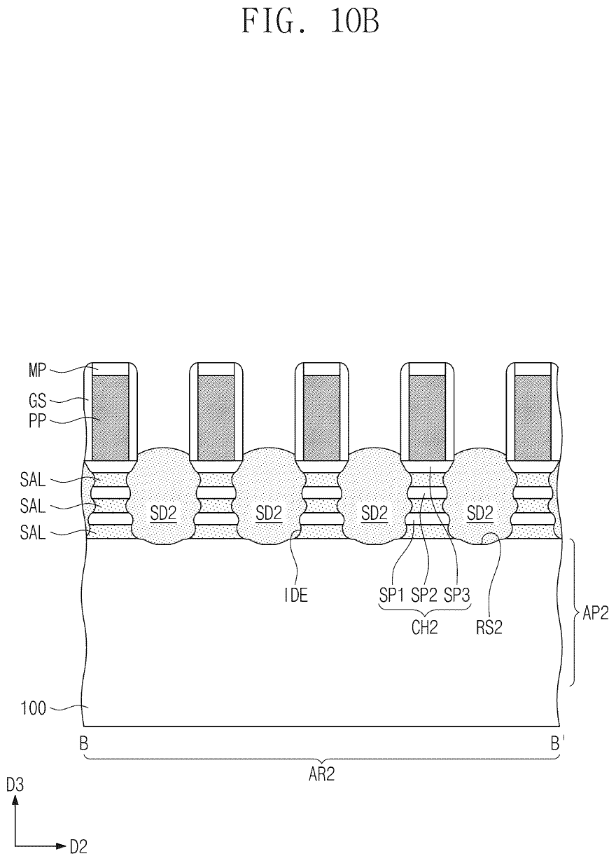

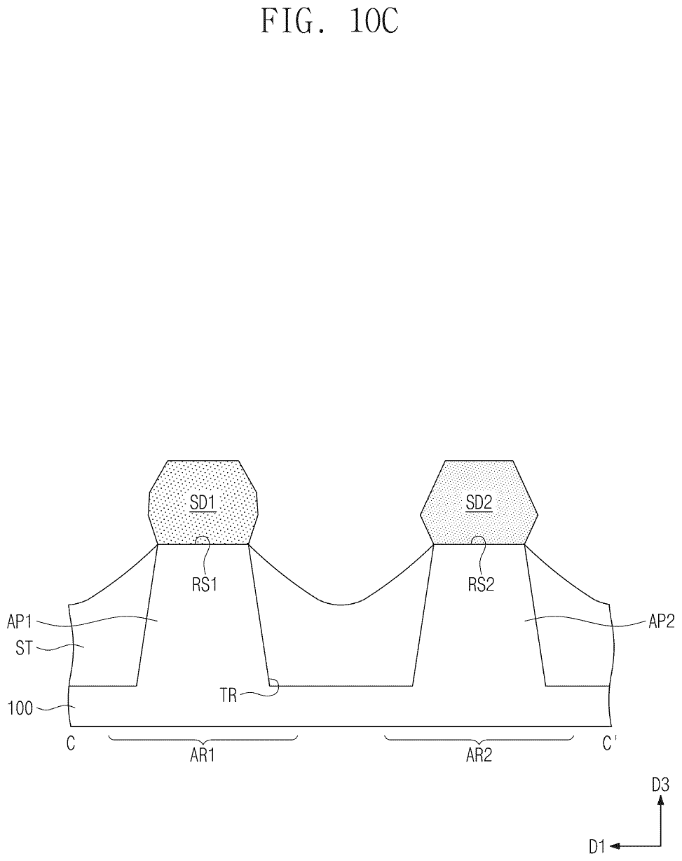

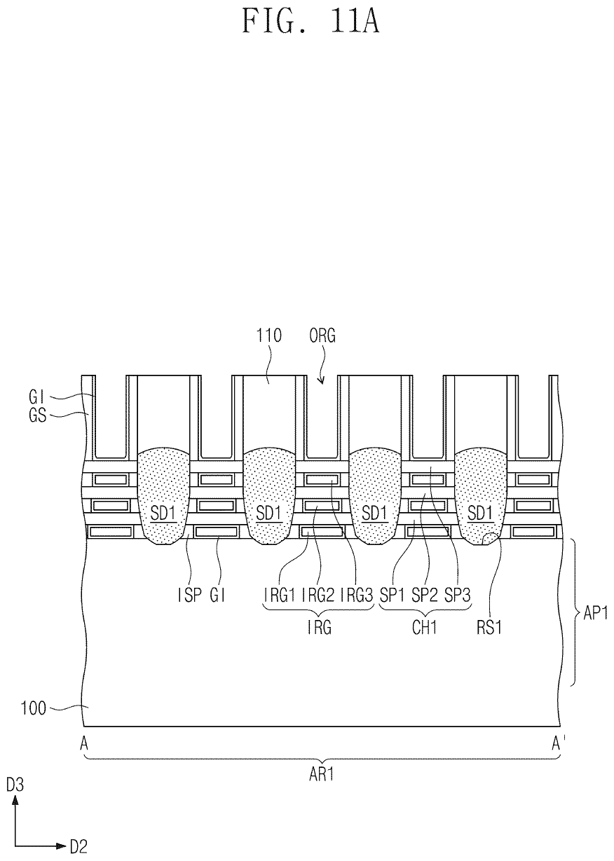

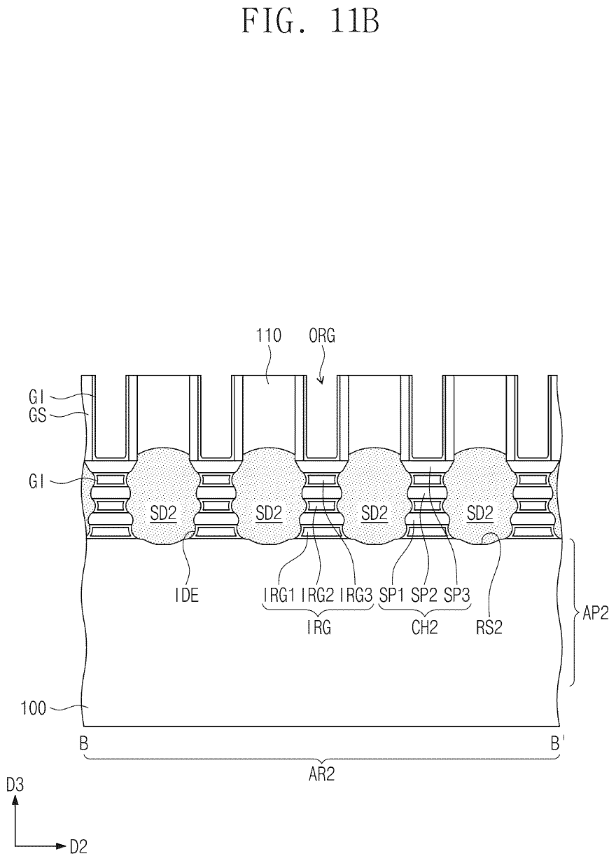

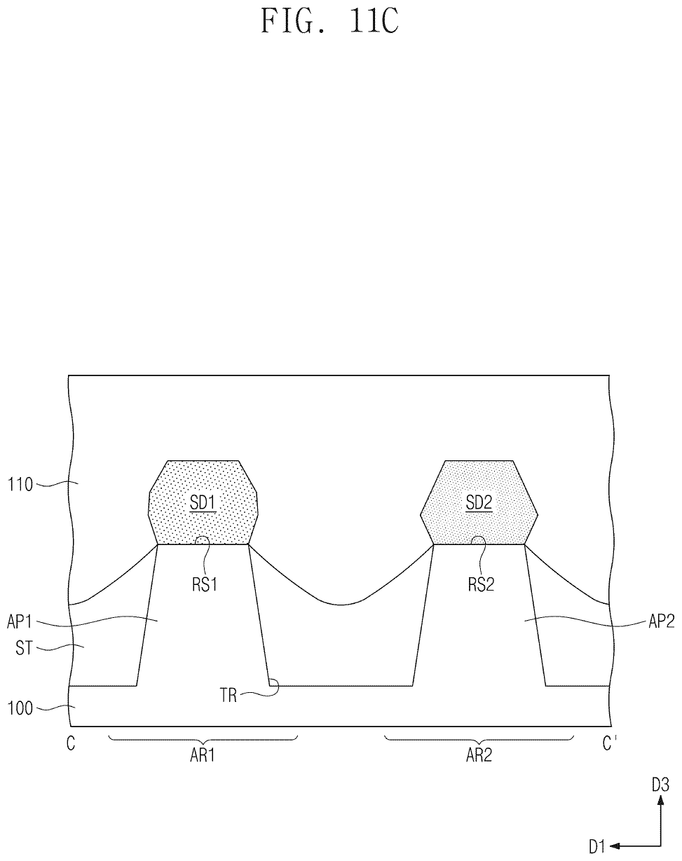

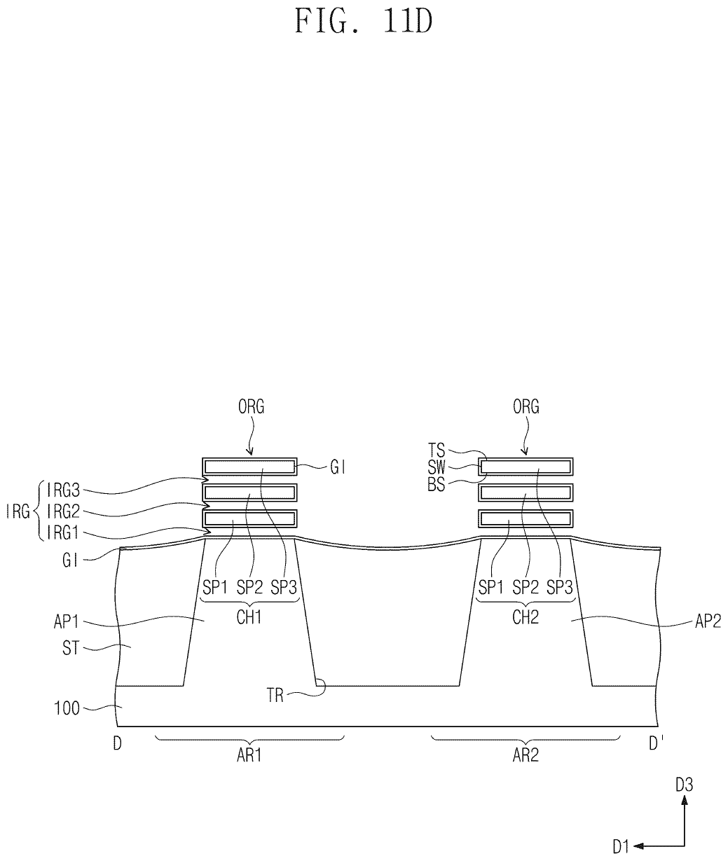

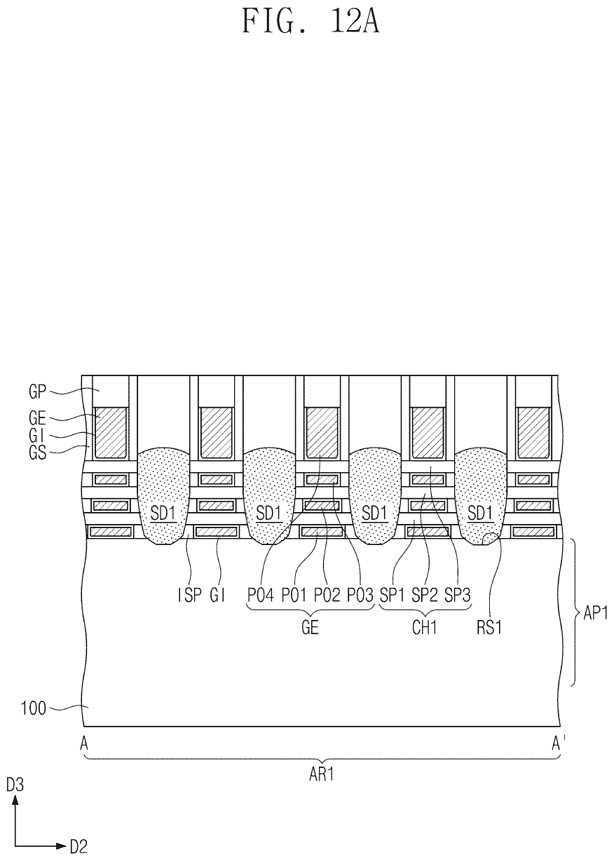

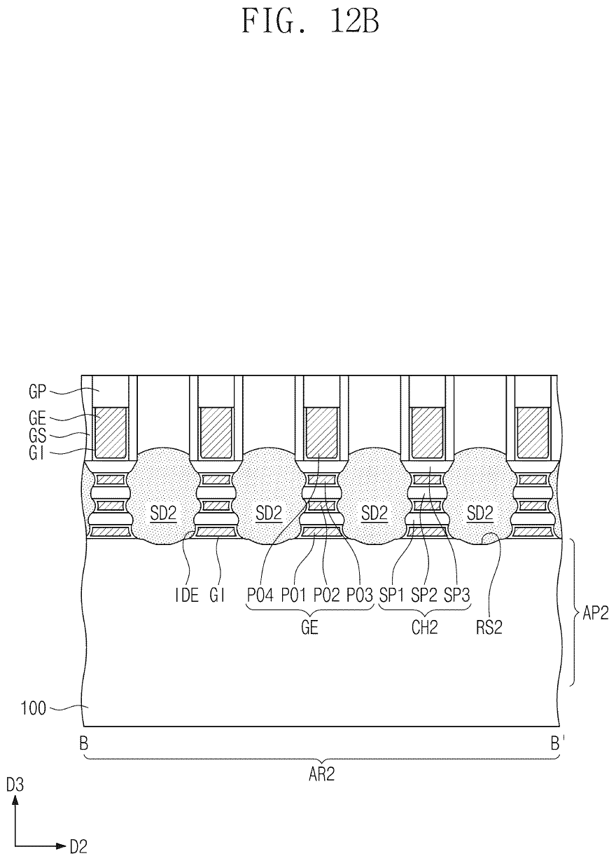

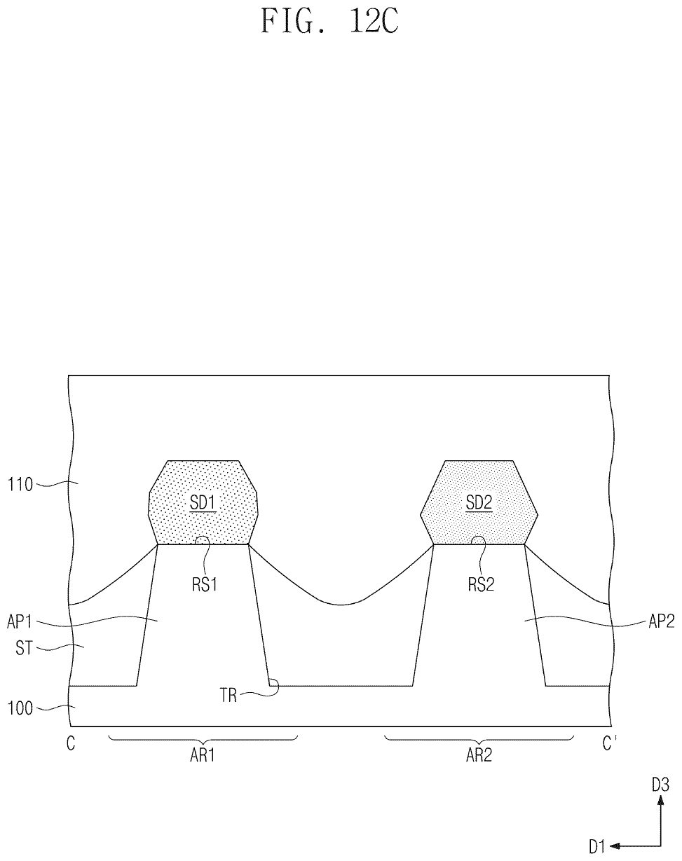

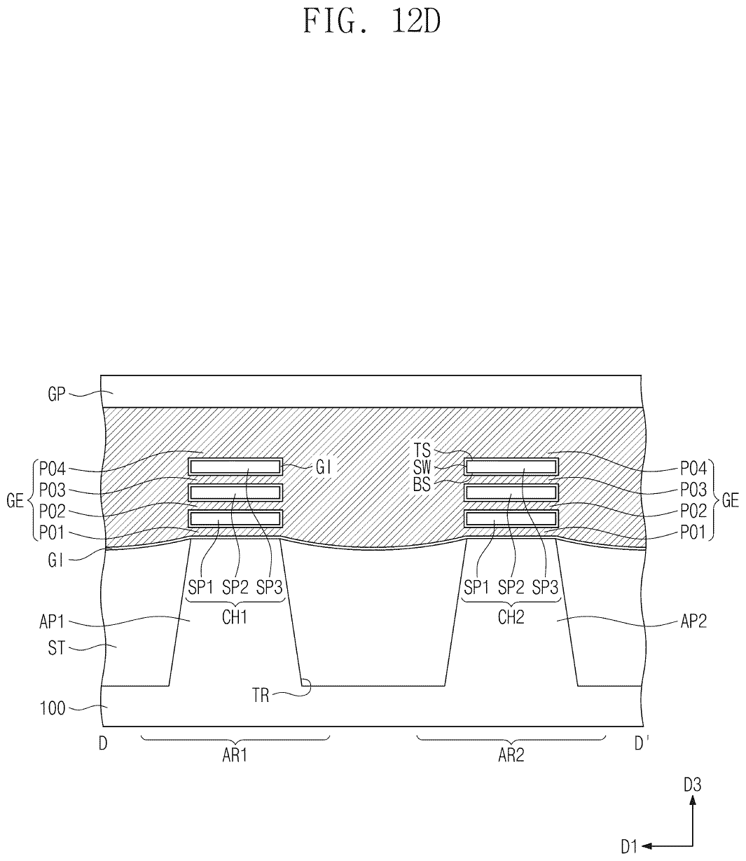

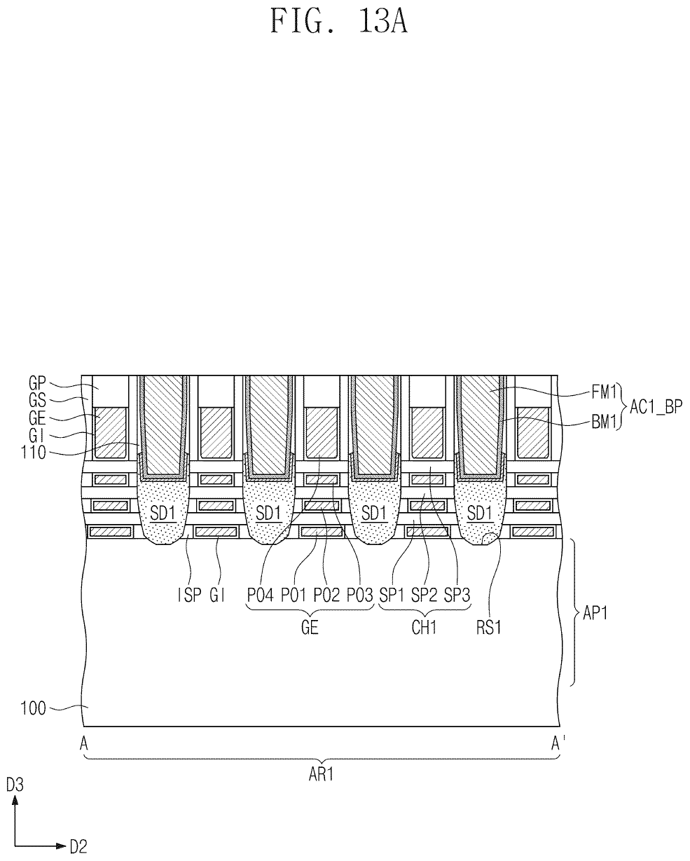

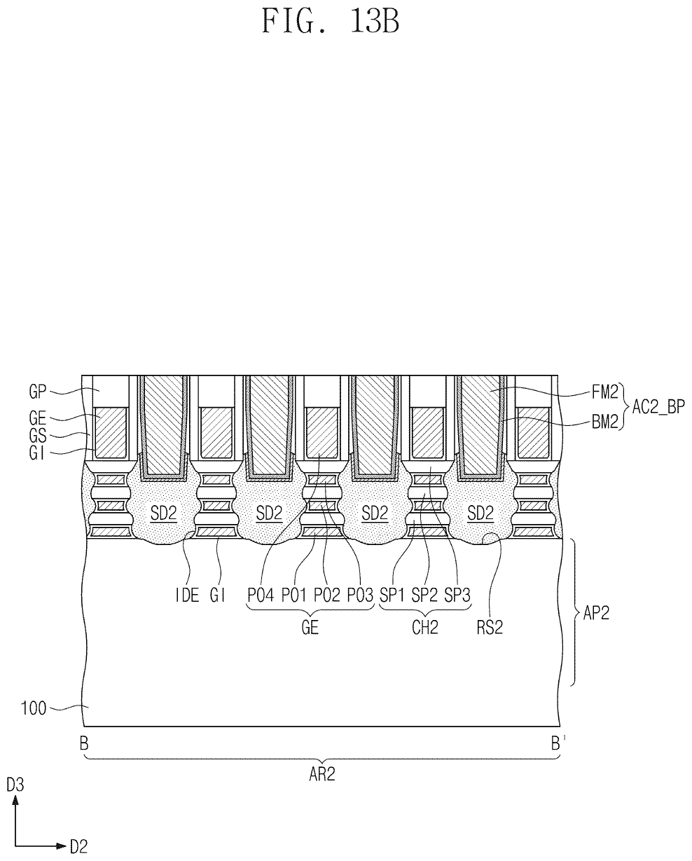

Referring to FIGS. 10A to 10C, first source/drain patterns SD1 may be correspondingly formed in the first recesses RS1. For example, a selective epitaxial growth (SEG) process may be performed in which an inner sidewall of the first recess RS1 is used as a seed layer to form an epitaxial layer that fills the first recess RS1. The epitaxial layer may be grown from a seed or the substrate 100 and the first, second, and third semiconductor patterns SP1, SP1, and SP3 exposed by the first recess RS1. For example, the SEG process may include chemical vapor deposition (CVD) or molecular beam epitaxy (MBE).

In an embodiment of inventive concepts, the first source/drain pattern SD1 may include the same semiconductor element (e.g., Si) as that of the substrate 100. While the first source/drain pattern SD1 is formed, impurities (e.g., phosphorus, arsenic, or antimony) may be in-situ implanted to allow the first source/drain pattern SD1 to have an n-type conductivity. Alternatively, after the formation of the first source/drain pattern SD1, impurities may be implanted into the first source/drain pattern SD1.

Second source/drain patterns SD2 may be correspondingly formed in the second recesses RS2. For example, a selective epitaxial growth (SEG) process may be performed such that an inner sidewall of the second recess RS2 is used as a seed to form the second source/drain pattern SD2.

In an embodiment of inventive concepts, the second source/drain pattern SD2 may include a semiconductor element (e.g., SiGe) whose lattice constant is greater than that of a semiconductor element of the substrate 100. While the second source/drain pattern SD2 is formed, impurities (e.g., boron, gallium, or indium) may be in-situ implanted to allow the second source/drain pattern SD2 to have a p-type conductivity. Alternatively, after the formation of the second source/drain pattern SD2, impurities may be implanted into the second source/drain pattern SD2.

Referring to FIGS. 11A to 11D, a first interlayer dielectric layer 110 may be formed to cover the first and second source/drain patterns SD1 and SD2, the hardmask patterns MP, and the gate spacers GS. For example, the first interlayer dielectric layer 110 may include a silicon oxide layer.

The first interlayer dielectric layer 110 may be planarized until top surfaces of the sacrificial patterns PP are exposed. An etch-back or chemical mechanical polishing (CMP) process may be employed to planarize the first interlayer dielectric layer 110. The hardmask patterns MP may all be removed during the planarization process. As a result, the first interlayer dielectric layer 110 may have a top surface coplanar with those of the sacrificial patterns PP and those of the gate spacers GS.

The exposed sacrificial patterns PP may be selectively removed. The removal of the sacrificial patterns PP may form an outer region ORG that exposes the first and second channel patterns CH1 and CH2 (see FIG. 11D). The removal of the sacrificial patterns PP may include performing a wet etching process using an etchant that selectively etches polysilicon.

The sacrificial layers SAL exposed through the outer region ORG may be selectively removed to form inner regions IRG (see FIG. 11D). For example, an etching process that selectively etches the sacrificial layers SAL may be performed such that only the sacrificial layers SAL may be removed while leaving the first, second, and third semiconductor patterns SP1, SP2, and SP3. The etching process may have a high etch rate with respect to silicon-germanium having a relatively high germanium concentration. For example, the etching process may have a high etch rate with respect to silicon-germanium whose germanium concentration is greater than about 10 at %.

The etching process may remove the sacrificial layers SAL on the first and second active regions AR1 and AR2. The etching process may be a wet etching process. An etching material used for the etching process may promptly etch the sacrificial layer SAL whose germanium concentrate is relatively high.

Referring back to FIG. 11D, as the sacrificial layers SAL are selectively removed, the stacked first, second, and third semiconductor patterns SP1, SP2, and SP3 may remain on each of the first and second active patterns AP1 and AP2. The removal of the sacrificial layers SAL may form first, second, and third inner regions IRG1, IRG3, and IRG3.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring back to FIGS. 11A to 11D, a gate dielectric layer GI may be formed on the exposed first, second, and third semiconductor patterns SP1, SP2, and SP3. The gate dielectric layer GI may be formed to surround each of the first, second, and third semiconductor patterns SP1, SP2, and SP3. The gate dielectric layer GI may be formed in each of the first, second, and third inner regions IRG1, IRG2, and IRG3. The gate dielectric layer GI may be formed in the outer region ORG.

Referring to FIGS. 12A to 12D, a gate electrode GE may be formed on the gate dielectric layer GI. The gate electrode GE may include first, second, and third inner electrodes PO1, PO2, and PO3 that are respectively formed in the first, second, and third inner regions IRG1, IRG2, and IRG3, and may also include an outer electrode PO4 formed in the outer region ORG. The gate electrode GE may be recessed to have a reduced height. A gate capping pattern GP may be formed on the recessed gate electrode GE.

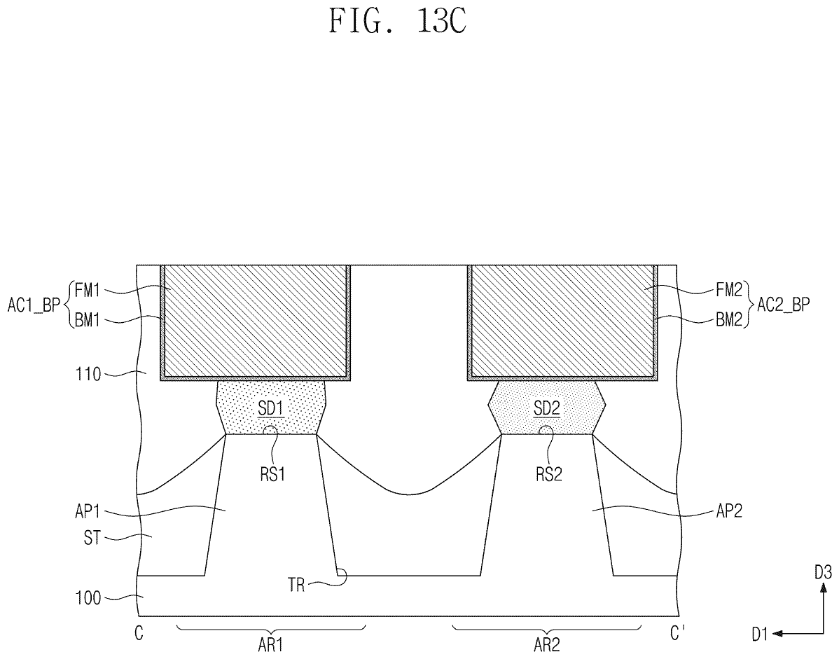

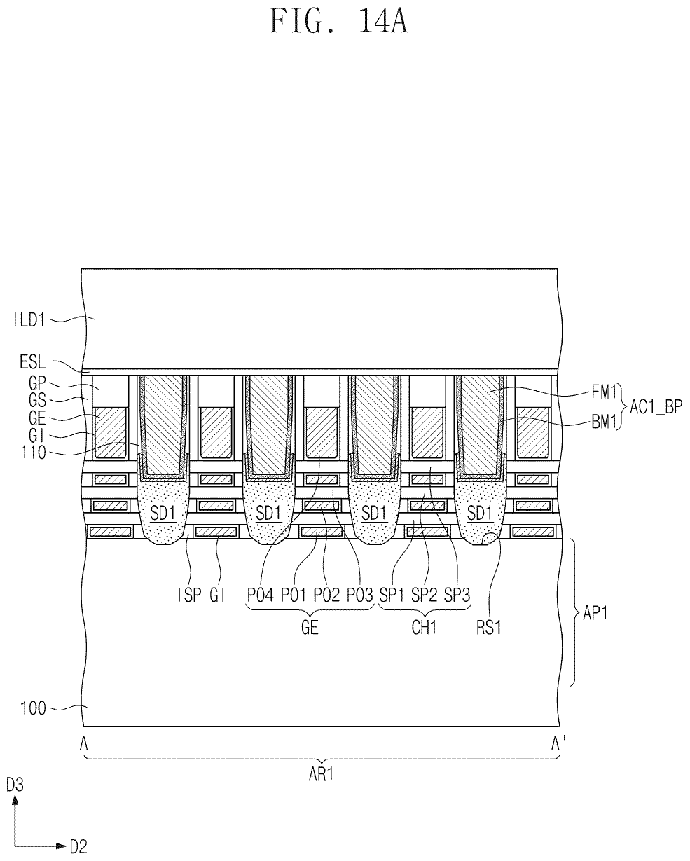

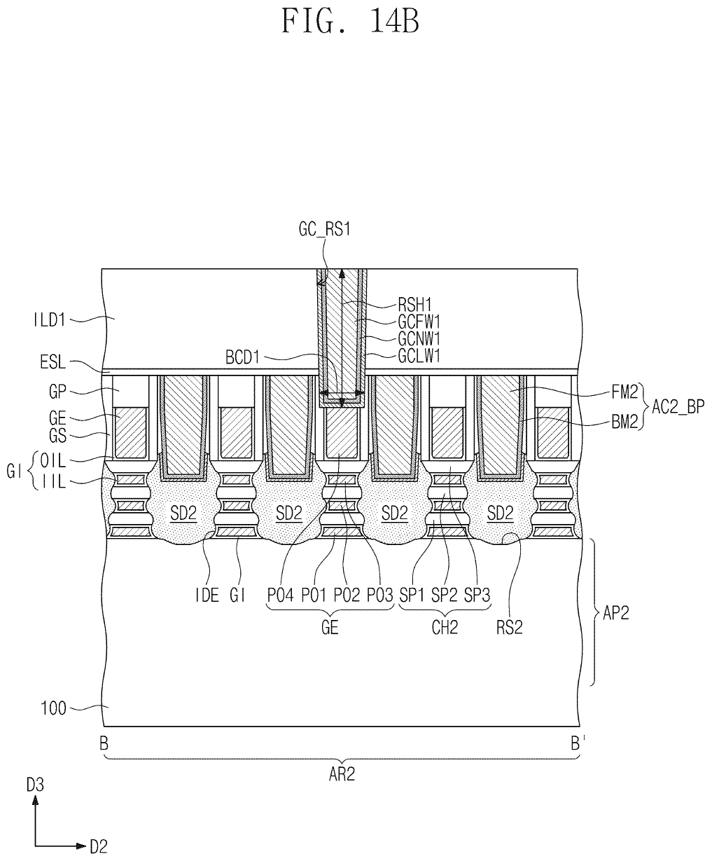

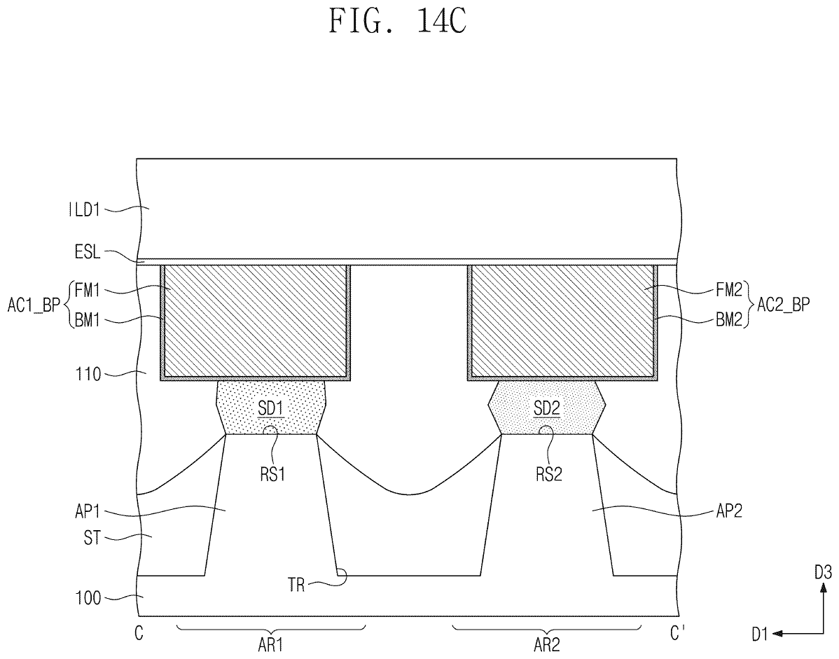

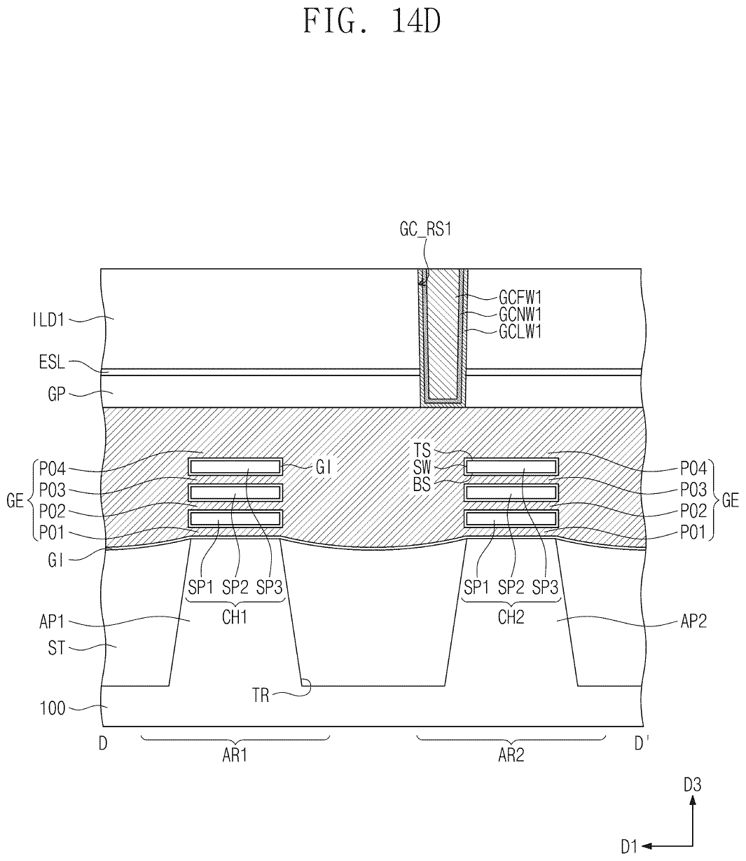

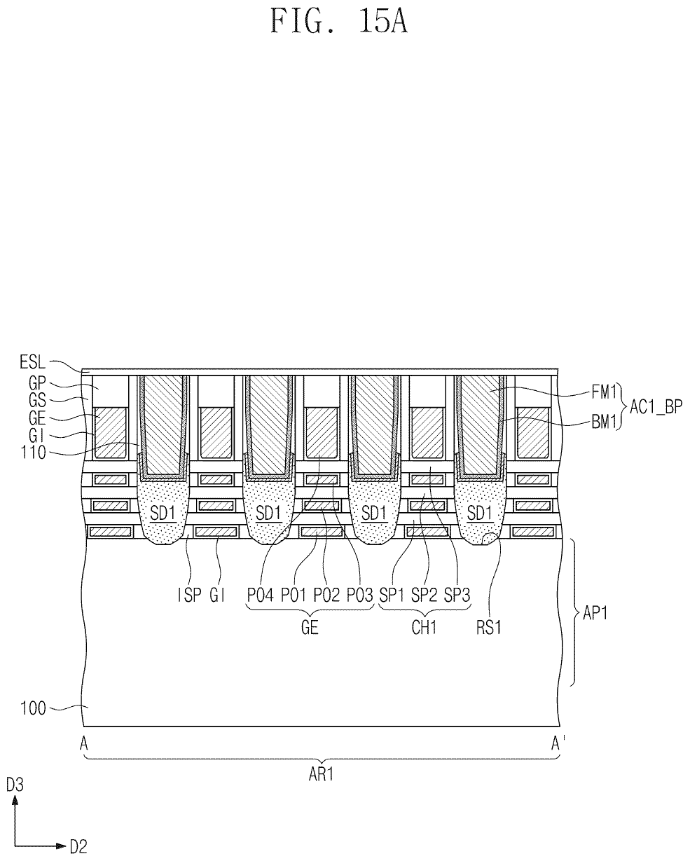

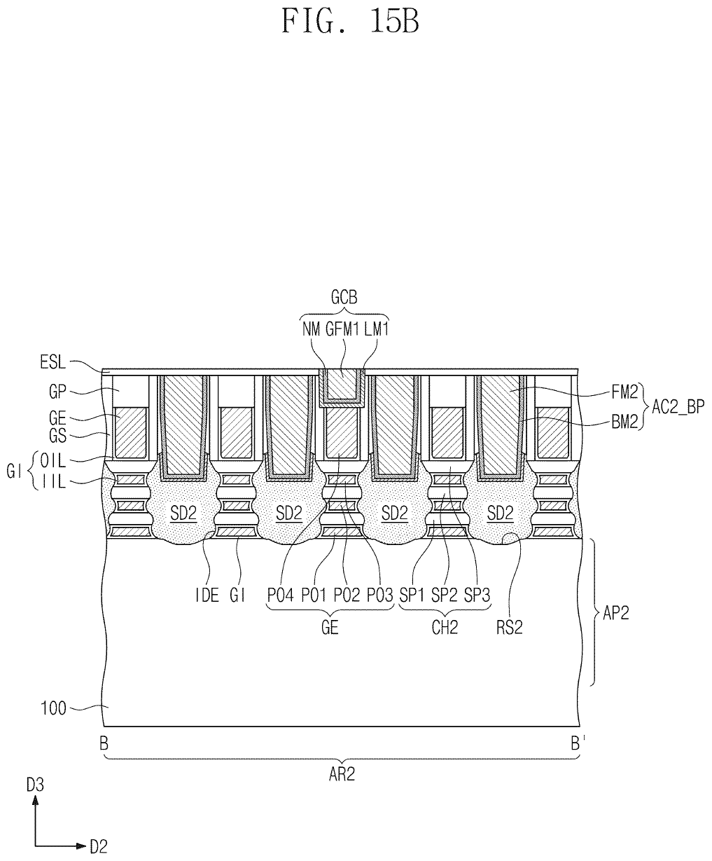

Referring to FIGS. 13A to 13C, a first recess and a second recess may be formed to penetrate the first interlayer dielectric layer 110. A dry etching process may be performed to form the first and second recesses. The first recess and the second recess may penetrate the first interlayer dielectric layer 110 to extend to an upper portion of the first source/drain pattern SD1 and an upper portion of the second source/drain pattern SD2, respectively.

The formation of a first lower active contact AC1_BP may include forming a first barrier pattern BM1 in the first recess and forming a first conductive pattern FM1 on the first barrier pattern BM1. The formation of a second lower active contact AC2_BP may include forming a second barrier pattern BM2 in the second recess and forming a second conductive pattern FM2 on the second barrier pattern BM2.

For example, the formation of the first and second conductive patterns FM1 and FM2 may include depositing a conductive material on each of the first and second barrier patterns BM1 and BM2, and performing a planarization process. The planarization process may include a chemical mechanical polishing (CMP) process which is performed until top surfaces of the gate capping pattern GP and the gate spacer GS are exposed.

The first barrier pattern BM1 and the second barrier pattern BM2 may be conformally formed in corresponding recesses, and may include a metal or a metal nitride layer. For example, the first barrier pattern BM1 and the second barrier pattern BM2 may include TiN. The first conductive pattern FM1 and the second conductive pattern FM2 may include low-resistance metal. For example, the first conductive pattern FM1 and the second conductive pattern FM2 may include tungsten.

Referring to FIGS. 14A to 14D, an etch stop layer ESL may be formed on the gate capping pattern GP and the first interlayer dielectric layer 110. A first preliminary dielectric layer ILD1 may be formed on the etch stop layer ESL. The etch stop layer ESL may include a silicon nitride layer, and the first preliminary dielectric layer ILD1 may include a silicon oxide layer.

A first gate contact recess GC_RS1 may be formed to penetrate the first preliminary dielectric layer ILD1 and the etch stop layer ESL. The first gate contact recess GC_RS1 may penetrate the first preliminary dielectric layer ILD1, the etch stop layer ESL, and the gate capping pattern GP to thereby extend to a top surface of the outer electrode PO4. The first gate contact recess GC_RS1 may be formed by performing a dry etching process.

The dry etching process may form the first gate contact recess GC_RS1 having a first aspect ratio. The first aspect ratio may be defined to indicate a ratio of a first height RSH1 of the first gate contact recess GC_RS1 to a first width BCD1 at a lower portion of the first gate contact recess GC_RS1. The first aspect ratio may be defined as a high aspect ratio. For example, the first aspect ratio may range from about 4 to about 5.

The formation of a preliminary lower gate contact may include forming a first liner layer GCLW1 in the first gate contact recess GC_RS1, forming a nucleation layer GCNW1 on the first liner layer GCLW1, forming a first filling layer GCFW1 on the nucleation layer GCNW1, and performing a chemical mechanical polishing (CMP) process. The planarization process may include a chemical mechanical polishing (CMP) process which is performed until a top surface of the first preliminary dielectric layer ILD1 is exposed.

The first liner layer GCLW1 may cover bottom and lateral surfaces of the first gate contact recess GC_RS1. For example, the first liner layer GCLW1 may be conformally formed. The first liner layer GCLW1 may be deposited by performing a physical vapor deposition (PVD) process. For example, the first liner layer GCLW1 may include at least one metal selected from aluminum, copper, tungsten, molybdenum, and cobalt.

The nucleation layer GCNW1 may be conformally formed on the first liner layer GCLW1. The nucleation layer GCNW1 may be deposited by performing a pulsed nucleation layer (PNL) process. The nucleation layer GCNW1 may include boron and at least one metal selected from aluminum, copper, tungsten, molybdenum, and cobalt. For example, the nucleation layer GCNW1 may include tungsten and boron.

The first filling layer GCFW1 may be formed on the nucleation layer GCNW1. For example, the first filling layer GCFW1 may fill an empty space in the first gate contact recess GC_RS1 in which the first liner layer GCLW1 and the nucleation layer GCNW1 are formed. The first filling layer GCFW1 may be deposited by performing a chemical vapor deposition (CVD) process. For example, the first filling layer GCFW1 may include at least one metal selected from aluminum, copper, tungsten, molybdenum, and cobalt. A top surface of the first filling layer GCFW1 may be substantially coplanar with that of the first preliminary dielectric layer ILD1.

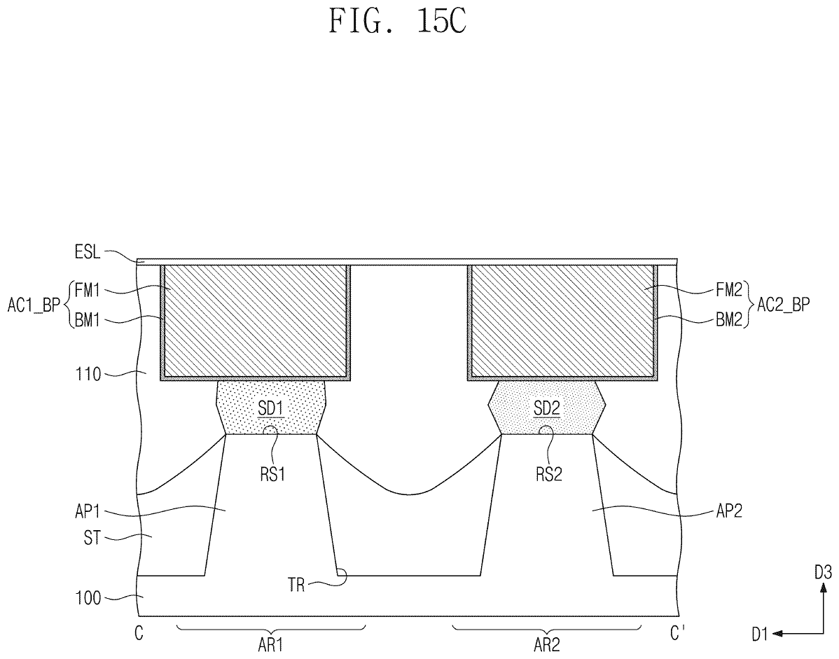

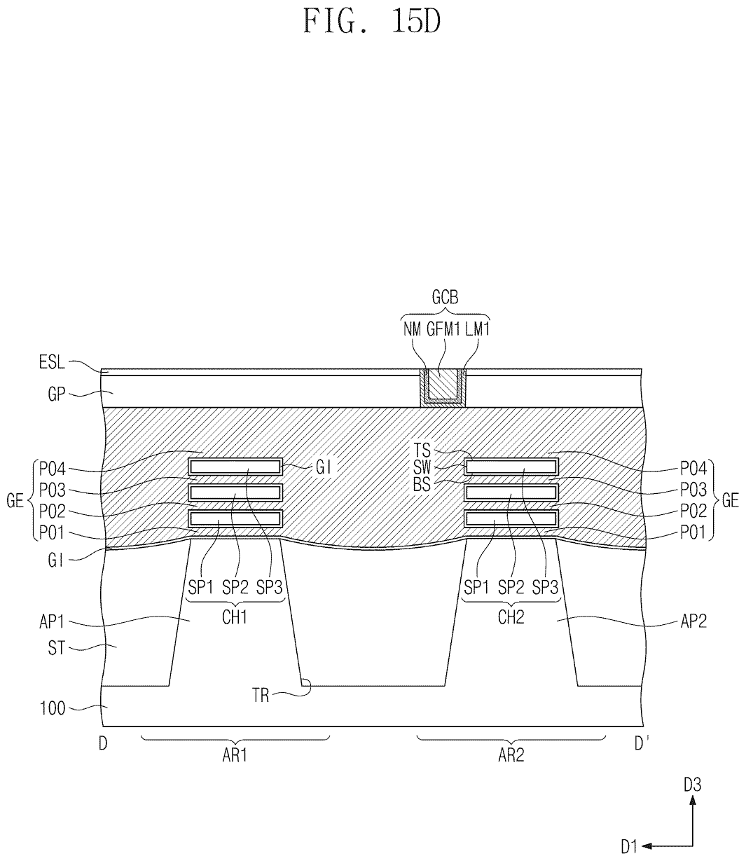

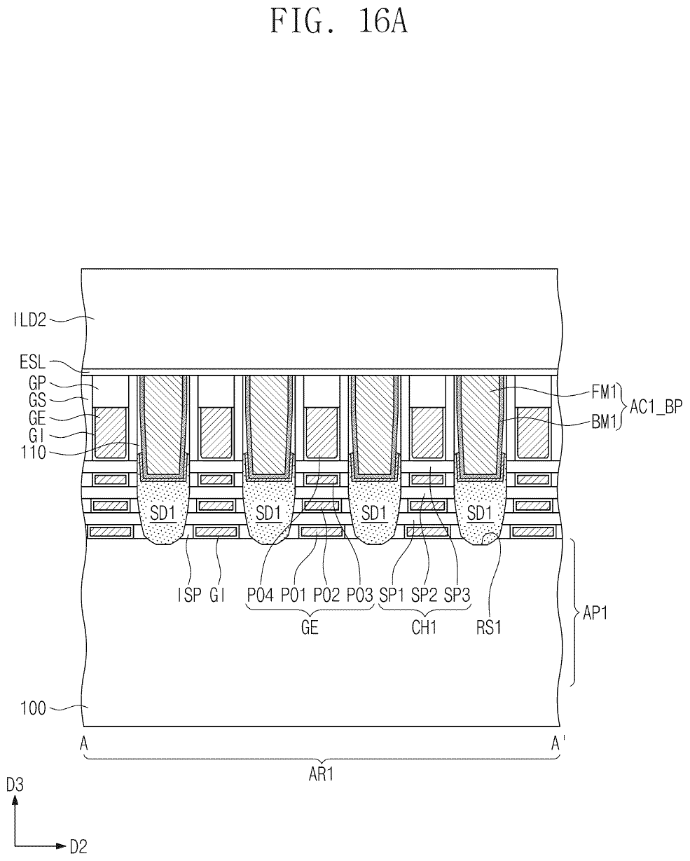

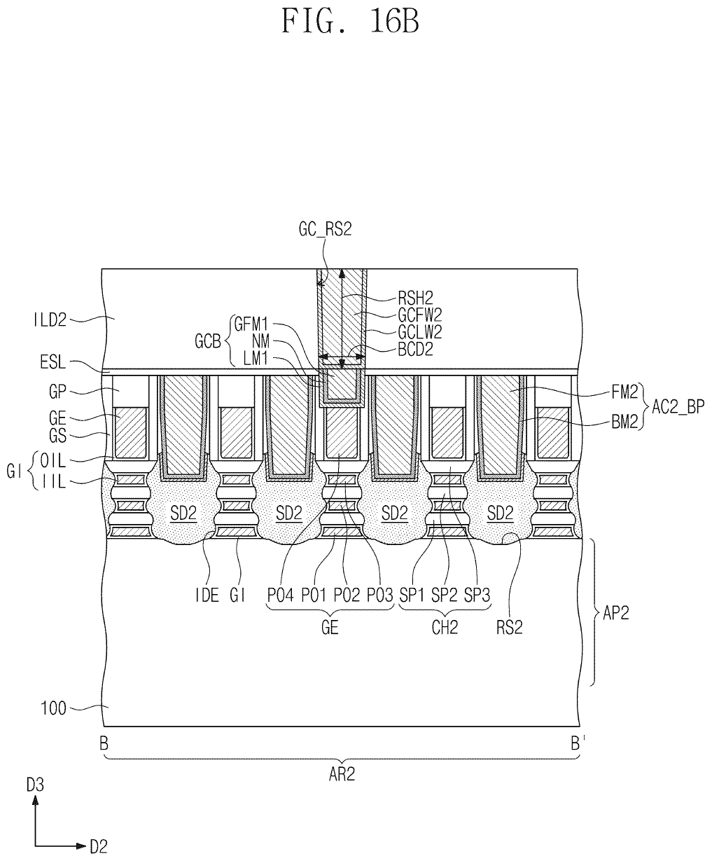

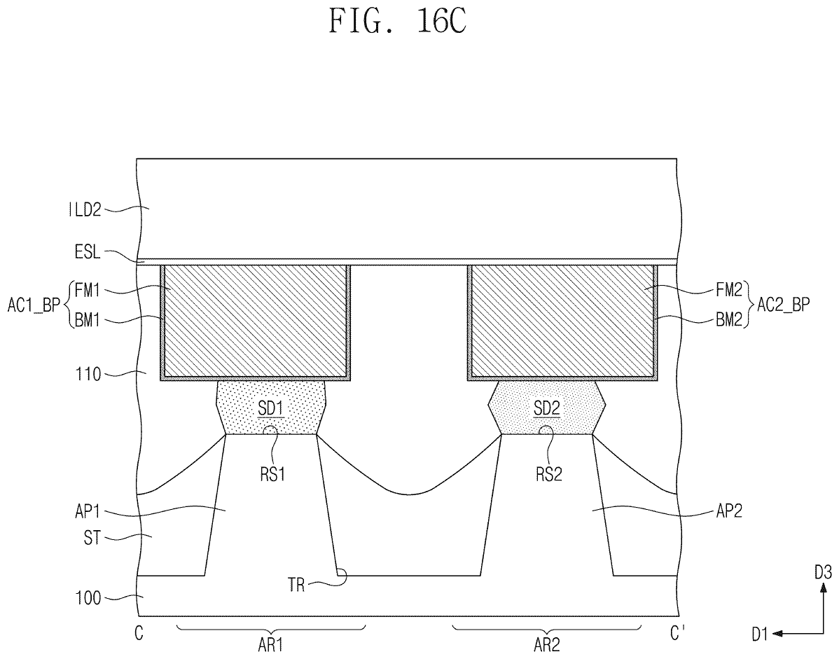

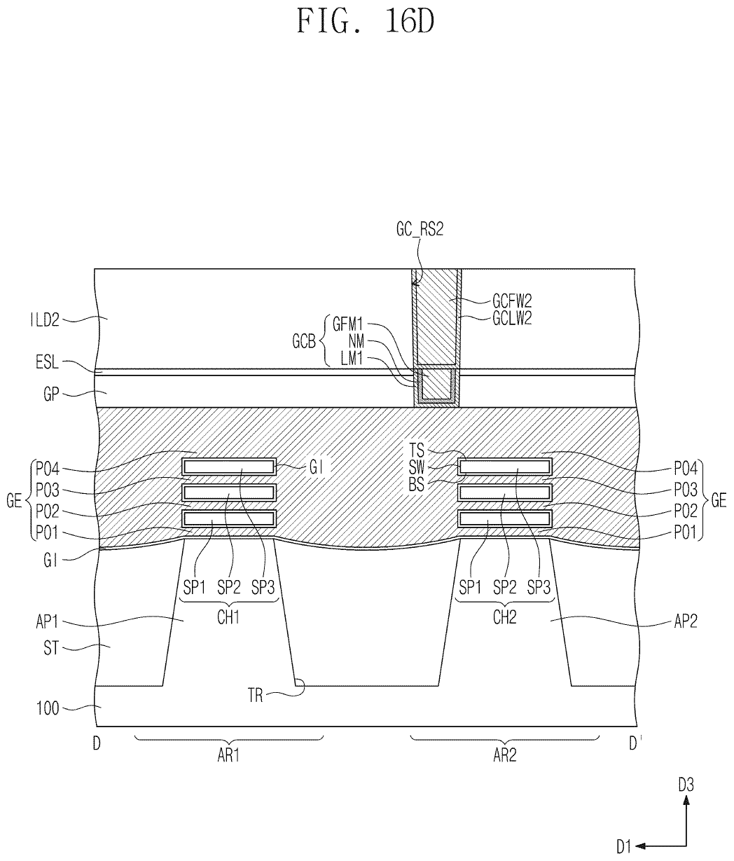

As the preliminary lower gate contact includes the nucleation layer GCNW1 between the first liner layer GCLW1 and the first filling layer GCFW1, it may be possible to limit and/or prevent the occurrence of void in the preliminary lower gate contact. As the nucleation layer GCNW1 is conformally deposited, the first gate contact recess GC_RS1 having a high aspect ratio may be completely filled with no voids. For example, no seam or slit may be created in the preliminary lower gate contact. Accordingly, it may be possible to improve a profile failure of a lower gate contact (see GCB of FIG. 15B), which will be discussed below.

Referring to FIGS. 15A to 15D, the first preliminary dielectric layer ILD1 and a portion of the preliminary lower gate contact may be recessed to form a lower gate contact GCB. The recessing may include performing a dry etching process or a wet etching process. The etch stop layer ESL have a low etch selectivity with respect to a chemical material or a gas that etches the first preliminary dielectric layer ILD1 and the preliminary lower gate contact, and thus may be utilized as a stop layer of etching.

Alternatively, the recessing may include performing a chemical mechanical polishing (CMP) process for planarization. When a chemical mechanical polishing (CMP) process is performed, the etch stop layer ESL may be utilized as an end point layer that serves as an end point detection (EPD) target. The first preliminary dielectric layer ILD1 and the preliminary lower gate contact may undergo the CMP process which continues until a top surface of the etch stop layer ESL is exposed.

The lower gate contact GCB may include a first liner pattern LM1 formed by recessing the first liner layer GCLW1, a nucleation pattern NM formed by recessing the nucleation layer GCNW1, and a first filling pattern GFM1 formed by recessing the first filling layer GCFW1. A top surface of the first filling pattern GFM1 may be substantially coplanar with that of the etch stop layer ESL.

Referring to FIGS. 16A to 16D, a second preliminary dielectric layer ILD2 may be formed on the etch stop layer ESL. The second preliminary dielectric layer ILD2 may include a silicon oxide layer. A second gate contact recess GC_RS2 may be formed to penetrate the second preliminary dielectric layer ILD2. The second gate contact recess GC_RS2 may extend to a top surface of the lower gate contact GCB. The second gate contact recess GC_RS2 may be formed by performing a dry etching process.

The dry etching process may form the first gate contact recess GC_RS2 having a second aspect ratio. The second aspect ratio may be defined to indicate a ratio of a second height RSH2 of the second gate contact recess GC_RS2 to a second width BCD2 at a lower portion of the second gate contact recess GC_RS2. The second aspect ratio may be defined as a low aspect ratio. For example, the second aspect ratio may range from about 2 to about 3.

The formation of a preliminary upper gate contact may include forming a second liner layer GCLW2 in the second gate contact recess GC_RS2 and forming a second filling layer GCFW2 on the second liner layer GCLW2.

The second liner layer GCLW2 may cover bottom and lateral surfaces of the second gate contact recess GC_RS2. For example, the second liner layer GCLW2 may be conformally formed. The second liner layer GCLW2 may be deposited by performing a physical vapor deposition (PVD) process. For example, the second liner layer GCLW2 may include at least one metal selected from aluminum, copper, tungsten, molybdenum, and cobalt.

The second filling layer GCFW2 may be formed on the second liner layer GCLW2. For example, the second filling layer GCFW2 may fill an empty space in the second gate contact recess GC_RS2 in which are formed the second liner layer GCLW2 is formed. The second filling layer GCFW2 may be deposited by performing a chemical vapor deposition (CVD) process. For example, the second filling layer GCFW2 may include at least one metal selected from aluminum, copper, tungsten, molybdenum, and cobalt. A top surface of the second filling layer GCFW2 may be substantially coplanar with that of the second preliminary dielectric layer ILD2.

The nucleation layer (see GCNW1 of FIG. 14B) may be removed by slurry at a higher rate than that of the second liner layer GCLW2 and the second filling layer GCFW2. When a nucleation layer is included in a preliminary upper gate contact, the preliminary upper gate contact may experience dishing or erosion after a chemical mechanical polishing (CMP) process which will be discussed below. According to some embodiments of inventive concepts, the preliminary upper gate contact may include no nucleation layer between the second liner layer GCLW2 and the second filling layer GCFW2, the occurrence of dishing or erosion may be limited and/or prevented in performing a second sub-CMP process which will be discussed below. Accordingly, there may be an increase in reliability of a semiconductor device fabricated by inventive concepts.

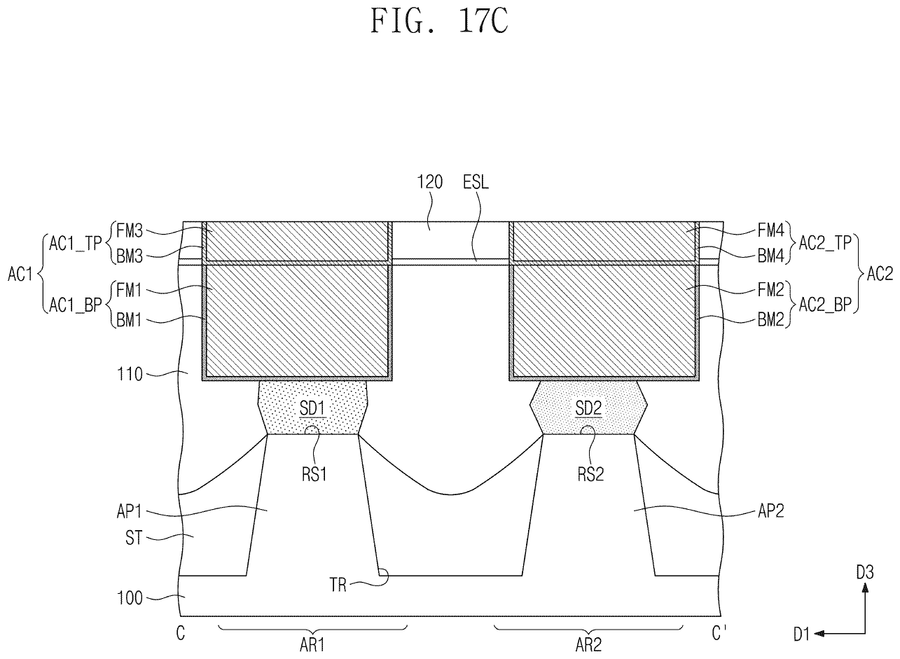

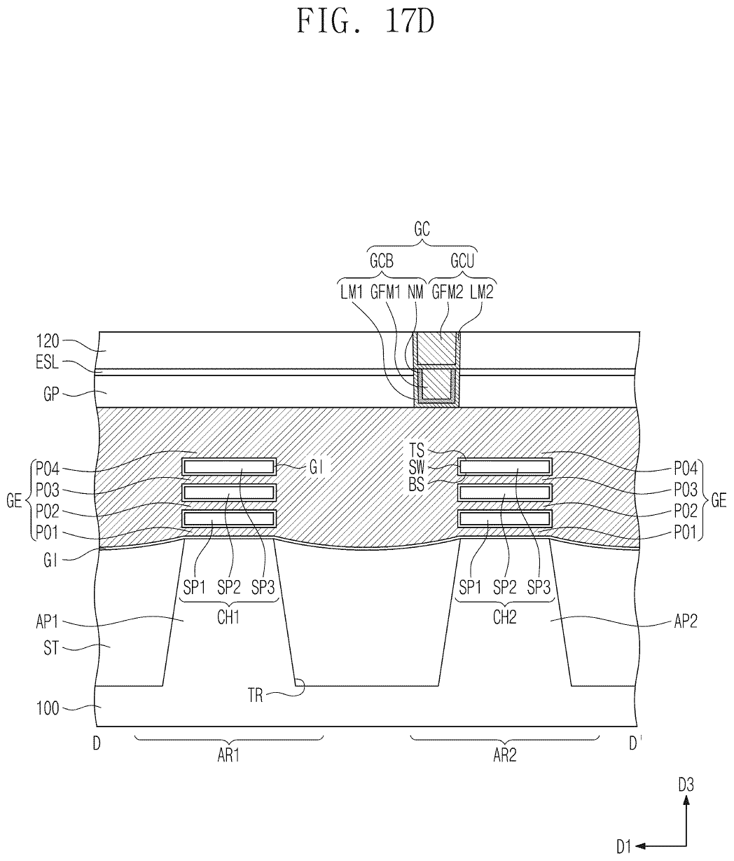

Referring to FIGS. 17A to 17D, a third recess and a fourth recess may be formed to penetrate the second preliminary dielectric layer (see ILD2 of FIG. 16B) and the etch stop layer ESL. A dry etching process may be performed to form the third and fourth recesses. The third recess and the fourth recess may penetrate the second preliminary dielectric layer (see ILD2 of FIG. 16B) and the etch stop layer ESL to respectively extend to the first lower active contact AC1_BP and the second lower active contact AC2_BP, respectively.

The formation of a first upper active contact AC1_TP may include forming a third barrier pattern BM3 in the third recess, and forming a third conductive pattern FM3 on the third barrier pattern BM3. The formation of a second upper active contact AC2_TP may include forming a fourth barrier pattern BM4 in the fourth recess, and forming a fourth conductive pattern FM4 on the fourth barrier pattern BM4.

For example, the formation of the third and fourth conductive patterns FM3 and FM4 may include depositing a conductive material on each of the third and fourth barrier patterns BM3 and BM4, and performing a planarization process. The performing the planarization process may include performing a first sub-CMP process and performing a second sub-CMP process.

For example, the first sub-CMP process may continue until the top surface of the second preliminary dielectric layer (see ILD2 of FIG. 16B) is exposed. The second sub-CMP process may continue until the preliminary upper gate contact is recessed to form an upper gate contact GCU. The second preliminary dielectric layer (see ILD2 of FIG. 16B) recessed by the second sub-CMP process may be called a second interlayer dielectric layer 120.

The third barrier pattern BM3 and the fourth barrier pattern BM4 may be conformally formed in corresponding recesses, and may include at least one metal selected from aluminum, copper, tungsten, molybdenum, and cobalt. For example, the third barrier pattern BM3 and the fourth barrier pattern BM4 may include tungsten. The third barrier pattern BM3 and the fourth barrier pattern BM4 may include low-resistance metal. For example, the third conductive pattern FM3 and the fourth conductive pattern FM4 may include tungsten.

The upper gate contact GCU may include a second liner pattern LM2 formed by recessing the second liner layer GCLW2 and a second filling pattern GFM2 formed by recessing the second filling layer GCFW2. The second filling pattern GFM2 may have a top surface substantially coplanar with that of the second interlayer dielectric layer 120.

Referring back to FIGS. 5A to 5D, separation structures DB may be formed on the first boundary BD1 and the second boundary BD2 of the single height cell SHC. The separation structure DB may penetrate from the second interlayer dielectric layer 120 to the gate electrode GE to extend into the active pattern AP1 or AP2. The separation structure DB may include a dielectric material, such as a silicon oxide layer or a silicon nitride layer.

A third interlayer dielectric layer 130 may be formed on the first and second active contact structures AC1 and AC2 and the gate contact structure GC. A first metal layer M1 may be formed in the third interlayer dielectric layer 130. A fourth interlayer dielectric layer 140 may be formed on the third interlayer dielectric layer 130. A second metal layer M2 may be formed in the fourth interlayer dielectric layer 140.

In a three-dimensional field effect transistor according to inventive concepts, a nucleation pattern may be included only in a lower gate contact of a gate contact structure, and thus it may be possible to limit and/or prevent the occurrence of void in the gate contact structure. In addition, no seam or slit may be present in the gate contact structure having a high aspect ratio, and thus it may be possible to improve profile failure of the gate contact structure. The occurrence of dishing or erosion at a top surface of the gate contact structure may be limited and/or prevented in performing a chemical mechanical polishing (CMP) process which will be discussed below. Accordingly, a semiconductor device according to inventive concepts may increase in reliability.

In a three-dimensional field effect transistor according to inventive concepts, a gate contact structure may be formed to have a double structure, and may thus decrease in resistance. No nucleation pattern may be included in an upper gate contact of the gate contact structure, and may therefore decrease in overall resistance. In consequence, a semiconductor device according to inventive concepts may increase in electrical properties.

Although inventive concepts have been described in connection with some embodiments of inventive concepts illustrated in the accompanying drawings, it will be understood by one of ordinary skill in the art that variations in form and detail may be made therein without departing from the spirit and essential features of inventive concepts. The above disclosed embodiments should thus be considered illustrative and not restrictive.

What is claimed is:

1. A semiconductor device, comprising:
a substrate including an active pattern;
a channel pattern on the active pattern, the channel pattern including a plurality of semiconductor patterns that are vertically stacked and spaced apart from each other;
a source/drain pattern connected to the plurality of semiconductor patterns;
a gate electrode on the plurality of semiconductor patterns, the gate electrode including a plurality of inner electrodes between neighboring semiconductor patterns of the plurality of semiconductor patterns and an outer electrode on an uppermost semiconductor pattern of the plurality of semiconductor patterns; and
a gate contact structure electrically connected to the outer electrode, wherein
the gate contact structure includes a lower gate contact on a top surface of the outer electrode and an upper gate contact on the lower gate contact, and
the lower gate contact includes a first liner pattern, a first filling pattern on the first liner pattern, and a nucleation pattern between the first liner pattern and the first filling pattern.

2. The semiconductor device of claim 1, wherein the nucleation pattern extends from a bottom surface of the first filling pattern to a lateral surface of the first filling pattern.

3. The semiconductor device of claim 2, wherein the nucleation pattern extends to a bottom surface of the upper gate contact.

4. The semiconductor device of claim 1, wherein the nucleation pattern includes boron and at least one of aluminum, copper, tungsten, molybdenum, and cobalt.

5. The semiconductor device of claim 4, wherein the nucleation pattern is non-crystalline or amorphous.

6. The semiconductor device of claim 4, wherein
the nucleation pattern is a tungsten (W) single layer deposited by performing a pulse nucleation layer (PNL) process.

7. The semiconductor device of claim 1, wherein
the upper gate contact includes a second liner pattern and a second filling pattern on the second liner pattern, and
the second liner pattern extends from a bottom surface of the second filling pattern to a lateral surface of the second filling pattern.

8. The semiconductor device of claim 7, wherein
the first liner pattern, the second liner pattern, the first filling pattern, and the second filling pattern independently includes at least one of aluminum, copper, tungsten, molybdenum, and cobalt.

9. The semiconductor device of claim 8, wherein the first liner pattern, the second liner pattern, the first filling pattern, and the second filling pattern are crystalline.

10. The semiconductor device of claim 8, wherein the first liner pattern and the second liner pattern each are a tungsten (W) layer deposited by performing a physical vapor deposition (PVD) process.

11. The semiconductor device of claim 8, wherein the first filling pattern and the second filling patterns each are a tungsten (W) layer deposited by performing a chemical vapor deposition (CVD) process.

12. The semiconductor device of claim 1, wherein a bottom surface of the upper gate contact, a top surface of the first liner pattern, a top surface of the first filling pattern, and a top surface of the nucleation pattern are in direct contact with each other.

13. The semiconductor device of claim 1, wherein a width in a first direction of the outer electrode is less than a width in the first direction of the gate contact structure.

14. A semiconductor device, comprising:
a substrate including an active pattern;
a channel pattern on the active pattern, the channel pattern including a plurality of semiconductor patterns that are vertically stacked and spaced apart from each other;
a source/drain pattern connected to the plurality of semiconductor patterns;
a gate electrode on the plurality of semiconductor patterns; and
a gate contact structure electrically connected to the gate electrode, wherein
the gate contact structure includes a lower gate contact on the gate electrode and an upper gate contact on the lower gate contact,
the lower gate contact includes a first liner pattern, a first filling pattern on the first liner pattern, and a nucleation pattern between the first liner pattern and the first filling pattern,
the nucleation pattern includes metal and boron,
the nucleation pattern has a first boron concentration,
the first liner pattern and the first filling pattern each have a second boron concentration, and
the first boron concentration is greater than the second boron concentration.

15. The semiconductor device of claim 14, wherein the first boron concentration is in a range of 0.1 at % to 15 at %.

16. The semiconductor device of claim 14, wherein
the upper gate contact includes a second liner pattern and a second filling pattern on the second liner pattern,
the second liner pattern and the second filling pattern each have a third boron concentration, and
the first boron concentration is greater than the third boron concentration.

17. A semiconductor device, comprising:
a substrate including an active pattern;
a device isolation layer on the substrate and defining the active pattern;
a channel pattern on the active pattern, the channel pattern including a plurality of semiconductor patterns that are vertically stacked and spaced apart from each other;
a source/drain pattern connected to the plurality of semiconductor patterns;
a gate electrode on the plurality of semiconductor patterns;
a gate dielectric layer between the gate electrode and neighboring semiconductor patterns among the plurality of semiconductor patterns;
a gate spacer on a sidewall of the gate electrode;
a gate contact structure electrically connected to the gate electrode, the gate contact structure including a lower gate contact in direct contact with the gate electrode and an upper gate contact on the lower gate contact;
an active contact structure electrically connected to the source/drain pattern, the active contact structure including a lower active contact adjacent to the source/drain pattern and an upper active contact on the lower active contact;
a metal-semiconductor compound layer between the active contact structure and the source/drain pattern;
a first metal layer on the gate contact structure, the first metal layer including a power line and a first wiring line electrically connected to the active contact structure; and
a second metal layer on the first metal layer, the second metal layer including a second wiring line electrically connected to first metal layer, wherein
a top surface of the upper gate contact and a top surface of the upper active contact are coplanar with each other, and
a level of a bottom surface of the upper gate contact is higher than a level of a bottom surface of the upper active contact.

18. The semiconductor device of claim 17, wherein
the lower gate contact includes a first liner pattern, a first filling pattern on the first liner pattern, and a nucleation pattern between the first liner pattern and the first filling pattern,
the nucleation pattern extends from a bottom surface of the first filling pattern to a lateral surface of the first filling pattern,
the upper gate contact includes a second liner pattern and a second filling pattern on the second liner pattern,
the nucleation pattern includes tungsten (W) and boron (B), and
the nucleation pattern has a non-crystalline or amorphous structure.

19. The semiconductor device of claim 18, wherein the first liner pattern, the second liner pattern, the first filling pattern, and the second filling pattern have a crystalline structure.

20. The semiconductor device of claim 17, wherein
the lower active contact includes a first barrier pattern and a first conductive pattern on the first barrier pattern,
the upper active contact includes a second barrier pattern and a second conductive pattern on the second barrier pattern,
the first conductive pattern and the second conductive pattern includes at least one of aluminum, copper, tungsten, molybdenum, and cobalt,
the first barrier pattern includes a metal layer or a metal nitride layer, and
the second barrier pattern is a tungsten (W) layer deposited by physical vapor deposition (PVD).
